(19) United States
(12) Patent Application Publication
(10) Pub. No.: US 2025/0299293 A1
(43) Pub. Date: Sep. 25, 2025

(54) OBTAINING HIGH RESOLUTION INFORMATION FROM LOW RESOLUTION IMAGES

(71) Applicant: ASML Netherlands B.V., Veldhoven (NL)

(72) Inventors: Alexandru ONOSE, Eindhoven (RO); Scott Anderson MIDDLEBROOKS, Duizel (NL); Markus Gerardus Martinus Maria VAN KRAAIJ, Eindhoven (NL); Tiago BOTARI, Eindhoven (NL); Anagnostis TSIATMAS, San Jose, CA (US)

(73) Assignee: ASML Netherlands B.V., Veldhoven (NL)

(21) Appl. No.: 18/864,463

(22) PCT Filed: Jul. 11, 2023
(86) PCT No.: PCT/EP2023/069172

§ 371 Date: Nov. 8, 2024

Related U.S. Application Data
(60) Provisional application No. 63/470,582, filed on Jun. 2, 2023.

(30) Foreign Application Priority Data
Jul. 15, 2022 (EP) 22185297.3

(51) Int. Cl. G06T 3/4046; G06T 7/00; H01J 37/26

(52) U.S. Cl. CPC G06T 3/4046; G06T 7/0004; H01J 37/265; G06T 2207/10061; G06T 2207/20081; G06T 2207/20084; G06T 2207/30108

(57) ABSTRACT

A method is proposed of using low-resolution images of at least one product produced by one or more imaging processes, and imaging models characterizing the imaging processes, to determine values for plurality of numerical parameters which collectively define a product model of the at least one product. The determination of the values is performed by forming a loss function based on the acquired images, the imaging models, and the numerical parameters of the model, and performing a minimization algorithm to minimize the loss function with respect to the numerical parameters. Due to prior knowledge of the product encoded in the loss function, the product model may comprise reconstructed images which have a higher resolution than the low-resolution images.

### CROSS-REFERENCE TO RELATED APPLICATIONS

This application claims priority of U.S. application 63/470,582 which was filed on 2 Jun. 2023 and EP application 22185297.3 which was filed on 15 Jul. 2022 which are incorporated herein in its entirety by reference.

### FIELD

The present invention relates to methods and systems for using acquired images of at least one product of a fabrication process, to form a product model of the product(s), such as a product model which contains information having a higher spatial resolution than the acquired images.

### BACKGROUND

A lithographic apparatus is a machine constructed to apply a desired pattern of material onto a substrate. A lithographic apparatus can be used, for example, in the manufacture of integrated circuits (ICs). A lithographic apparatus may, for example, project a patterned electromagnetic radiation beam generated by a patterning device onto a layer of radiation-sensitive material (resist) provided on a substrate. The term “patterning device” as employed in this text should be broadly interpreted as referring to a device that can be used to endow an incoming electromagnetic radiation beam with a patterned cross-section, corresponding to a pattern that is to be created in a target portion of the substrate. The patterning device may, for example, be a mask (or reticle) which causes selective transmission (in the case of a transmissive mask) or reflection (in the case of a reflective mask) of the radiation beam impinging on the mask, according to a pattern on the mask. The patterned beam changes the physical properties of portions of the resist which receive the radiation.

By a repeated process of depositing layers to the substrate (including layers of resist and other layers), patterning the resist layers using a radiation beam with a patterned cross-section, and selectively removing portions of the resist layers based on their different physical properties, a patterned structure with multiple layers can be formed on the substrate. The wavelength of the radiation determines the minimum size of features which can be formed on the substrate.

Many processes are known for imaging products of a fabrication process to check for fabrication defects. Such tools include brightfield imaging tools, dark field imaging tools and scanning electron microscope (SEM) tools. These tools have different advantages and drawbacks. In brightfield imaging, a sample is illuminated with light having a range of wavelengths (e.g. “white” light), and an image is formed using light transmitted or reflected by the sample. Brightfield imaging tools are typically used to detect coarse imaging defects. These tools are fast, and large areas of the device can be measured readily as millions of images, but the resolution of the resulting images is low, so that they are not readily suitable for making metrology measurements, such as of the size of any defects, or of the size of any structures formed in the products, etc., so it is hard to use them for detecting fine imaging defects.

### SUMMARY

The invention relates to methods and systems for obtaining information describing at least one product of a fabrication process based on a plurality of acquired images of the at least one product. The images may optionally be acquired by the same imaging process, but more generally multiple imaging processes may be used to capture different ones of the images.

In general terms, the present invention proposes using the images and corresponding imaging model(s) characterizing the corresponding imaging process(es), to determine values for plurality of numerical parameters which collectively define a product model of portion(s) of the at least one product. The determination of the numerical values is performed by forming a loss function based on the acquired images, the imaging model(s), and the numerical parameters of the model, and performing a minimization algorithm to minimize the loss function with respect to the numerical parameters. In implementations, the product model describes the product(s) with a higher spatial resolution than the captured images do.

The determination of the numerical values may employ a loss value representative of a difference between the acquired images and a result of applying the imaging model(s) to the product model. This loss value may be included as a term in the loss function, or an upper limit on the loss value may be used as a constraint on the minimization algorithm.

Based on the product model following the determination of the numerical parameters, a defect inspection process may be carried out. For example, areas of the product(s) with suspected defects may be identified, and the identified areas are then subject to further inspection (e.g. by a different imaging process). Alternatively or additionally, the product model may be measured to obtain dimensions of the product(s).

The acquired images may comprise multiple images of a single portion of the product, e.g. captured with different corresponding imaging processes. For example, an imaging process performed by an imaging device may be characterized by at least one imaging parameter, and each imaging process may correspond to a different realisation of the at least one imaging parameter. The at least one imaging parameter may for example be selected from the group consisting of:
a distance of a sensor of the imaging device from the at least one product;
an orientation of the at least one product with respect to an imaging direction in which the images are captured in the imaging process;
a translational position of the at least one product transverse to an imaging direction in which the images are captured in the imaging process;
a frequency (e.g. a frequency range) of electromagnetic radiation used in the imaging process;
a focal position of the imaging device relative to the product (“focus”); and
an exposure time used in capturing the image (“dose”). All of these may be considered control parameters of the imaging process, in the sense that the imaging system permit them to be controlled (e.g. by an operator).

Alternatively or additionally, the acquired images may be images of different corresponding imaging areas of the at least one product, at which the product is expected to have similar structures, e.g. because the imaging areas of the product were created based on respective design data (e.g. graphic design system (GDS) data) which was identical for the different imaging areas, or at least met a similarity criterion (e.g. being identical for at least a certain proportion of the imaging areas). For example, if the product has a repeating structure with a certain periodicity, the acquired images may include images of different corresponding imaging areas spaced apart on the product according to this periodicity. Furthermore, the acquired images may include images of corresponding imaging areas which are at the same location on different ones of the products (i.e. if the products are semi-conductor wafers, the imaging regions may include imaging regions on different wafers, which are at the same location with reference to a centre of the corresponding wafer).

In this case, the product model includes a respective model portion for each of the imaging regions having similar structures, and loss function may include a term which penalises differences between the model portions. Each model portion may be defined by a subset of the numerical parameters of the product model. In this way, information contained in the images and relating to the similar structures is shared among the model portions. The discrepancy term may be a term which penalizes the rank of a concatenation of the subsets of the numerical parameters defining the respective model portions. For example, as described below, the model portions may be in the form of images of the imaging regions having similar structures (“reconstructed images” which indicate how the product would look if it had been imaged by an imaging process having better spatial resolution than the actual imaging process), and in this case the discrepancy term may penalise the rank of a concatenation of the reconstructed images. More generally, the discrepancy term may be a rank of a concatenation of the subsets of the numerical parameters defining the model portions.

Many, though not all, imaging processes in effect apply a point spread function to imaged structures in a product. In this case the imaging model comprises a convolution model, e.g. based on an array of values indicative of the values of respective points on a point spread function.

One example of a product model, as noted above, is that the product model includes one or more reconstructed images (two-dimensional arrays of intensity values) which indicate how the product would look if it had been imaged by an imaging process which provides higher spatial resolution than the actual imaging process. For example, the product model may include a corresponding reconstructed image for each of the acquired images, and the reconstructed images may include information about the product(s) with a higher spatial resolution than the corresponding acquired images. This is possible because the information about each reconstructed image can be gathered from multiple ones of the acquired images, and because the loss function can be chosen to encode knowledge about the products (i.e. minimising the loss function corresponds to obtaining a product model which has a higher a priori likelihood of being correct). Thus, this example of the present disclosure makes it possible to use multiple low spatial-resolution images (e.g. brightfield images) to obtain higher spatial resolution images of the products.

In the case that the imaging process applies a point spread function to imaged structures, features which are just outside the imaging areas, may have an effect on the acquired images. For that reason, the reconstructed images may correspond to regions of the product which extend outside the corresponding imaging areas (e.g. they may include a margin around the corresponding imaging area on all sides of the imaging area, i.e. a peripheral margin encircling the imaging area). The imaging model not only applies the convolution model to the reconstructed images, but also preferably applies a mask to the result, so as to trim the result of the convolution to contain only pixels corresponding to locations in the corresponding imaging area.

As noted, the reconstructed images may contain higher spatial resolution information than the acquired images, and furthermore, the reconstructed images may have a higher pixel resolution (i.e. a greater number of pixels per unit distance on the product(s)) than the acquired images. In this case, the imaging model includes as a pixel resolution reduction model which, when applied to the reconstructed images (before or after applying the convolution model and the mask, if they are present), reduces their pixel resolution to be equal to that of the acquired images.

To encourage the reconstructed images to have a low background intensity, and thus a high dynamic range, the loss function may include at least one regularization term based on a norm of the intensity values. Furthermore, since it is known that typical products include structures having well-defined edges, the regularization term may include a structural term which encourages the formation of edges in the two-dimensional array of intensity values. The regularization term may be based on applying a transform (e.g. a wavelet transform and/or a transform which extracts image gradients) to the reconstructed images to obtain transform values and the regularization term may comprise a sum over the transform values of a function of each transform value.

As well as determining the numerical parameters of the product model, the method may include inferring the imaging model(s) from the acquired images, by inferring the values of the imaging parameters defining the imaging model(s). In addition to, or instead of, the imaging parameters listed above (which may be considered control parameters), in the case of an imaging model that includes a convolution model the imaging parameters may include the array of values indicative of the values of respective points on a point spread function. While the point spread function typically depends on the selected focal position (and may depend on other control parameters), it is usually to some extent a function of the imaging system itself.

The imaging parameters may optionally be inferred as part of the minimization algorithm, i.e. as imaging parameters which minimize the loss function. Alternatively, some or all of the imaging parameters may be determined experimentally, for example by imaging a target having a known geometry. If the target includes an object having a diameter in each of the directions transverse to the imaging direction which is less than the spatial resolution of the imaging process (e.g. less than a half-width of the point spread function in those directions), the array of values indicative of the values of the respective points on the point spread function may be the intensity values of the image of the object.

The loss function includes a plurality of terms multiplied by corresponding hyper-parameters. The values of the hyper-parameters may be selected by performing the method repeatedly for different corresponding trial values of the hyper-parameters, and selecting the values for the hyper-parameters from the trial values of the hyper-parameters using a selection criterion. For example, the criterion may be to select those trial values of the hyper-parameters which minimize the value the loss function (or at least of certain terms of the loss function) after performing the minimization algorithm with respect to the numerical parameters of the production model. In principle, though other selection criterion might be used, e.g. based on reducing the time which the minimization algorithm takes to converge to a solution.

Although, as described above, the product model may be comprise reconstructed image(s), it may alternatively (or additionally) be defined based on numerical parameters which define respective geometrical parameters of the at least one product. These numerical parameters may be any geometrical parameters, chosen based on prior knowledge of the structures which the fabrication process is intended to form (e.g. based on the design data which was used to configure the fabrication process).

For example, the design data may specify that the fabrication process should produce the product including at least one elongate element. In this case, the numerical parameters may include a position of the elongate element in the product, a length of the elongate element in the elongation direction; a width of the elongate structure transverse to the elongation direction; an angle between the length direction of the elongate element and a reference direction; or the angle between the respective length directions of two elongate elements in the product.

Alternatively or additionally, the design data may specify that the at least one product includes a plurality of layers spaced apart in a depth direction, and the numerical parameters include numerical parameters which respectively indicate one of: a translational offset transverse to the depth direction of two structures in the at least one product in different respective said layers; an angular offset transverse to the depth direction of the respective length directions of two elongate structures in the at least one product in different respective layers; or a spacing in the depth direction between two structures in the product.

The present concepts may be applied to acquired images captured by an imaging process which relies on any imaging modality. In one example, the imaging modality is bright-field microscopy. However, the imaging modality may alternatively be dark-field microscopy, or an imaging modality which is not reliant on electromagnetic radiation, such as scanning electron microscopy (SEM).

Once the numerical parameters of the product model have been determined, the product model may be used in a number of ways. A first way, as mentioned above, is to measure it to obtain numerical data describing the product. For example, in the case that the product model includes reconstruction images(s), distance values in the image can be measured to obtain dimensions of structures in the product. These dimensions may be compared with the design data to determine the accuracy of the fabrication process. If the difference between the design data and the measured dimensions of structures in the product is above a threshold (tolerance) an indication can be generated that an anomaly is present. The threshold thus constitutes an anomaly criterion.

Other possibility would be for an anomaly criterion to be based on observed differences between model portions describing respective parts of the product which are supposed to be similar according to the design data. For example, if the product model is a set of reconstructed images including imaging portions of the at least one product which, according to the design data, include the same structure, an anomaly criterion can be based on whether a measure of discrepancy between the reconstructed images is above a threshold, such as whether an elongate element in the structure has a measured length and/or width and/or orientation in one of the reconstruction images which differs by more than a threshold from the measured length and/or width and/or orientation of the corresponding elongate element in another of the reconstructed images.

The anomaly detection process may be performed repeatedly for successive products of the fabrication process, e.g. by determining that a product model relating to a newly produced product meets the anomaly criterion. For example, upon the fabrication process producing a new product, the present method may be carried out based on acquired images of the new product, and optionally also based on acquired images captured from a product from a preceding performance of the fabrication process, such as the immediately preceding performance.

Upon determining that an anomaly criterion is met, an additional inspection process can be carried out, e.g. using a different imaging modality which provides images with higher spatial resolution than the acquired images (e.g. SEM if the acquired images were captured by bright-field microscopy).

The fact that an anomaly has been detected based on a difference between model portions corresponding to portions of the at least one product which are supposed to be similar (e.g. based on identical design data), does not imply which of the model portions contains the anomaly. Optionally, all the model portions used in determining that the anomaly criterion is met may be inspected by the additional inspection process. Alternatively, there may be a process, in the case that there are at least three model portions corresponding to portions of the at least one product which are supposed to be similar, of identifying which one of those model portions differs most from the others, so that the anomaly is most likely to be in that identified model portion, i.e. the exceptional model portion is likely to correspond to a defective imaging region of the product. For example, one way of identifying the defective imaging portions is by forming the loss function repeatedly for different respective proper subsets of the model portions and their corresponding acquired images, and performing the step of determining values for the numerical parameters for each subset. A defective one of the imaging regions may then be identified as an imaging region for which the value of the loss function following the minimization process is lower for subsets which omit the corresponding model portions than for subsets which include the corresponding model portions.

In some forms of the invention, the acquired images may be captured with a known positional relationship (e.g. the imaging process may indicate to high accuracy the position of the imaging region of each image on the product). Alternatively, the method may include a process inferring the imaging regions on the product (“registering the images”). This process may be performed as part of the minimization algorithm. For example, each of the images may be associated with a respective displacement vector indicating a translational position of the corresponding image on the at least one product (e.g. in a plane transverse to the imaging direction), and the displacement vectors may be determined during the minimization process. This procedure may be performed iteratively, e.g. by repeatedly: (i) performing the minimisation with respect to the numerical parameters of the product model based on current values of the displacement vector(s), and (ii) updating the displacement vectors (registration). Experimentally, it has been found that this process can achieve a highly accurate registration, e.g. accurate to a tolerance which is less than the pixel resolution of the acquired images (i.e. the tolerance is less than a distance on the product between points corresponding to the centres of two adjacent pixels of the acquired images, that is the “width” of a pixel).

Optionally, two of more of the imaging areas for a given one of the products may overlap, so that the images collectively form a contiguous area on the product. In this case, the product model may also include numerical parameters describing a contiguous area which is inferred from multiple ones of the images, effectively by stitching the acquired images together. One situation in which this may be useful is if the images are captured successively by passing the successive imaging regions of the at least one product under the imaging apparatus which captures the acquired images.

The present method is suitable for use, for example, in the case that that the fabrication process is a wafer fabrication process, such as a lithographic process.

The concept may be expressed as a method, or a computing system (e.g. a portion of a lithographic apparatus) programmed to perform the method. It may also be expressed as a computer program product (e.g. downloadable software or a program stored in non-transitory form on a recording medium, such as a CD-ROM) including program instructions operative to cause a processor to perform the method.

As noted above, optionally a plurality of the acquired images may be images of the same imaging region, captured using different imaging processes, such as imaging processes which are characterized by imaging parameter(s) which take different values in each imaging process. Possible imaging parameters include those listed above. This concept constitutes a second aspect of the invention, independent of the first aspect. The second aspect of the invention thus provides a method of measuring at least one product of a fabrication process, comprising: imaging the at least one product using an imaging system by an imaging process characterized by at least one imaging parameter, wherein an imaging unit of the imaging system captures multiple images of at least one imaging region of the at least one product for multiple different corresponding realisations of the at least one imaging parameter; and using the multiple images of the at least one imaging region collectively to obtain a product model of the at least one product. The method can be carried out by an imaging system including an imaging unit (e.g. including a camera) and a control system configured to vary the imaging parameters, e.g. comprising a drive system for moving the at least one product and/or the imaging unit, to vary imaging parameters relating to the relative transitional and/or orientation positions of the product and the imaging unit.

A third aspect of the invention relates to the provision and training of a neural network model configured to generate a reconstructed image of a target object from an input image of the target object. The reconstructed image represents the target object with a higher spatial resolution than the input image. The neural network may be trained using a training dataset comprising a plurality of training items. Each training item comprises an acquired image of a training object and a computationally generated high resolution training image corresponding to the respective acquired image. For example, the high resolution training images may be generated according to the first or second aspect of the invention. Alternatively, other known computational methods (e.g. other known iterative deconvolution methods) may be used to generate the high resolution training images. The training objects are products of the same fabrication process as the target object. Thus, in the absence of defects in the fabrication process, the training objects are substantially identical to the target object. Thus, the neural network is typically specific to the fabrication process, yet, ideally it is generated without knowledge of the design data which defines the fabrication process. The acquired training images may have substantially the same spatial resolution as the input image.

The expression “same fabrication process” may be defined here as meaning that the target object and the training objects are products (e.g. semiconductor products) fabricated according to the same design data. In other words, some or all of the target objects and training objects may be fabricated using different instances of fabrication equipment (e.g. lithographic equipment), but that fabrication equipment is controlled based on the same design data. Desirably, the fabrication equipment for all instances of the fabrication process is produced according to the same specifications (e.g. it is different instances of the same sort of lithographic equipment).

In one example, the target object may comprise an elongated object with a width that is substantially equal to a width of an elongated object comprised in the training objects. Additionally or alternatively, the target object may comprise an object with a diameter (e.g. width) that is substantially equal to a diameter of an object comprised in the training objects.

The above neural network (once trained) enables, for example, the generation of high resolution images from acquired, low resolution images in a computationally lightweight manner compared, for example, to the first and second aspects of the invention. This is achieved by training the above neural network with (acquired, low resolution and generated, high resolution) images of objects which are substantially identical to the target object, in the absence of defects. Trained in this way, the neural network is encouraged to learn a computationally inexpensive image-to-image mapping instead of a more complex image enhancement task, such as the first and second aspect of the invention. The above neural network invention may thereby improve the processing time needed to generate high resolution images and may enable applications that require the generation of high resolution images from acquired images in real-time. Furthermore, the process may be performed by a computer system operated by an individual who has only limited access to the design data, e.g. is not aware of how the training objects and target objects would appear if the fabrication process were operating perfectly.

Optionally, the neural network may further receive as input (during training and use) a corresponding imaging parameter characterizing the imaging process used to acquire the input image and the training images respectively.

Training the neural network model using the training dataset may comprise adjusting the network parameter to reduce a discrepancy between each of the generated high resolution training images of the training dataset and a respective output image generated by inputting the corresponding acquired training image into the neural network model.

The neural network model may comprise at least one of an auto-encoder, a variational auto-encoder, and a U-Net architecture.

### BRIEF DESCRIPTION OF THE DRAWINGS

Embodiments of the invention will now be described, by way of example only, with reference to the accompanying schematic drawings, in which:

FIG. 1 shows schematically a brightfield microscopy inspection tool;

FIG. 2 illustrates a first inspection task encountered in a semiconductor manufacturing process;

FIG. 3 illustrates a second inspection task encountered in a semiconductor manufacturing process;

FIG. 4 is a flow diagram of a method which is an embodiment of the present invention;

FIG. 5 illustrates schematically an example of the method of FIG. 4;

FIG. 6 contrasts an image captured by a system as illustrated in FIG. 1 with a higher resolution image obtained by the method of FIG. 5;

FIG. 7 illustrates a graphic data system (GDS) image of portion of a semiconductor product with an inserted scanning electron microscope (SEM) image of part of the location.

FIG. 8 illustrates an overlap of the GDS image with a high-resolution image recorded by the method of FIG. 5.

FIG. 9 shows how differences between a sequence of reconstructed images produced by the method of FIG. 5 based on a respective portions of one or more semiconductor products, permit defects to be identified.

FIG. 10 illustrates schematically an example neural network which is an embodiment of the present invention;

FIG. 11 is a flow diagram of an example method of using the neural network of FIG. 10.

FIG. 12 is a flow diagram of an example method of training the neural network of FIG. 10.

FIG. 13 illustrates a method of generating high resolution images from images acquired using different imaging modalities.

FIG. 14-16 show experimental results obtained by using the trained neural network of FIG. 10.

### DETAILED DESCRIPTION

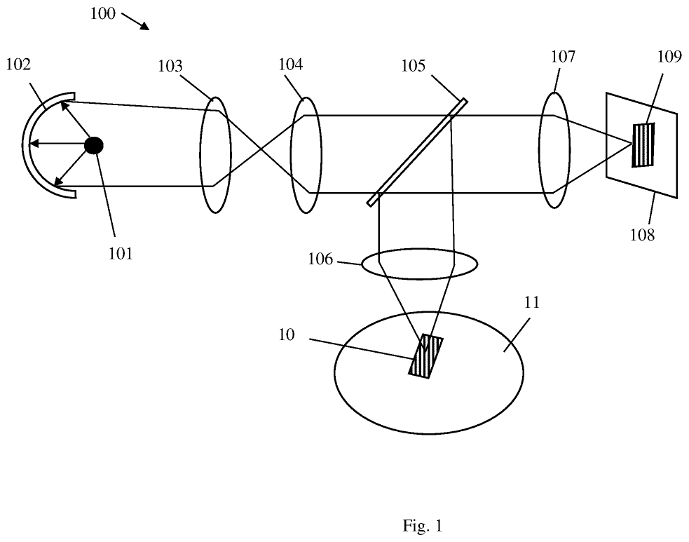

Referring firstly to FIG. 1, a schematic illustration is shown of a bright-field microscopy semiconductor inspection tool 100 suitable for use in an embodiment of the present invention. The tool is for obtaining images of a product, such as a fabricated die 10 on a semiconductor wafer 11. A light source 101 and mirror 102 generate an optical beam which is focused by lenses 103, 104, and then provided to a beam-splitter 105. The beam splitter 105 generates an optical beam (directed downwardly in FIG. 1) that is focused on the product 10 by an objective lens 106. Reflected light passes back through the objective lens 106, to the beam splitter 105 which redirects it towards the lens 107. Lens 107 focuses the beam onto a detector array 108. (A single detector array 108 is shown in FIG. 1 for visual simplicity, but more typically the reflected light is split and provided to a plurality of detector arrays.) The detector array 108 may be a TDI detector array, for example. The product 10 forms an image 109 on the detector array 108.

The semiconductor-inspection tool 100 is merely one example of a semiconductor-inspection tool that can be used with the techniques disclosed herein, and in fact any semi-conductor inspection tool can be used which forms image(s) of products, such as a dark-field microscopy inspection tool, or a scanning electron microscope imaging tool.

FIG. 2 shows schematically a first product inspection task which is encountered in inspecting products which are wafer fabricated, e.g. by a lithographic process, including integrated circuits. Two wafers 20, 21 are depicted, which may for example be successive products of a fabrication process. Each of the wafers 20, 21 includes multiple structures formed by the fabrication process with a periodicity indicated by the dashed lines. That is, within each of the rectangular regions (“fields”) defined between four of the dashed lines, the wafers 20 and 21 are intended to have substantially identical structures, defined by design data.

Furthermore, even within a single one of the fields, there may be multiple structures which are intended to be identical. Some of these structures are illustrated in FIG. 2 by dark circles. Thus, the circles 22 and 24 represent “identical” structures (according to the design data) within a single field on wafer 20. The circles 22, 23 represent “identical” structures at the same position within different fields on wafer 20. The circles 22, 25 represent “identical” structures at the same position on different wafers 20, 21.

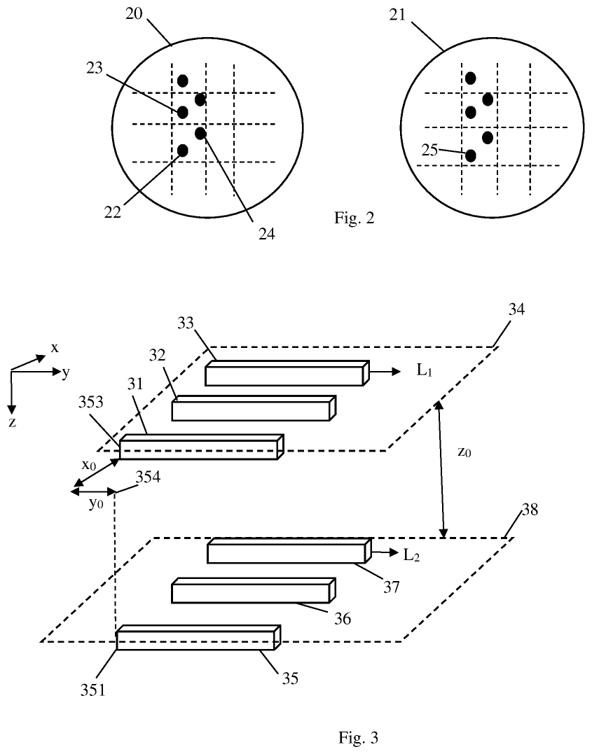

FIG. 3 shows schematically a second product inspection task which is encountered in inspecting products which are wafer fabricated, e.g. by a lithographic process, including integrated circuits. A structure is depicted which may, for example, be one of the structures 22, 23, 24, 25 of FIG. 2. The structure is defined in a three-dimensional coordinate system x-y-z.

The structure of FIG. 3 includes multiple (in this example, two) layers of elements 31, 32, 33, 35, 36, 37 disposed in respective planes 34, 38 separated by a distance z₀, in the z direction. The elements 31, 32, 33, 35, 36, 37 may for example be bodies of conductive material disposed within an insulating or semi-conducting matrix (not shown). The elements 31, 32, 33 in plane 34 are elongate, with the elongation direction for element 33 denoted by L₁. The elements 35, 36, 37 in plane 38 are also elongate, with the elongation direction for element 37 denoted by L₂. A certain corner of the elongate element 31 is labelled 353, and this has a displacement x₀ in the x-direction, and y₀ in the y-direction, from a corresponding corner 351 in the structure 35. The inspection task include determining the values of x₀, y₀ and z₀, together with the orientation of each of the directions L₂, and L₃ in the x-y plane, and/or an angle between the directions L₂, and L₃.

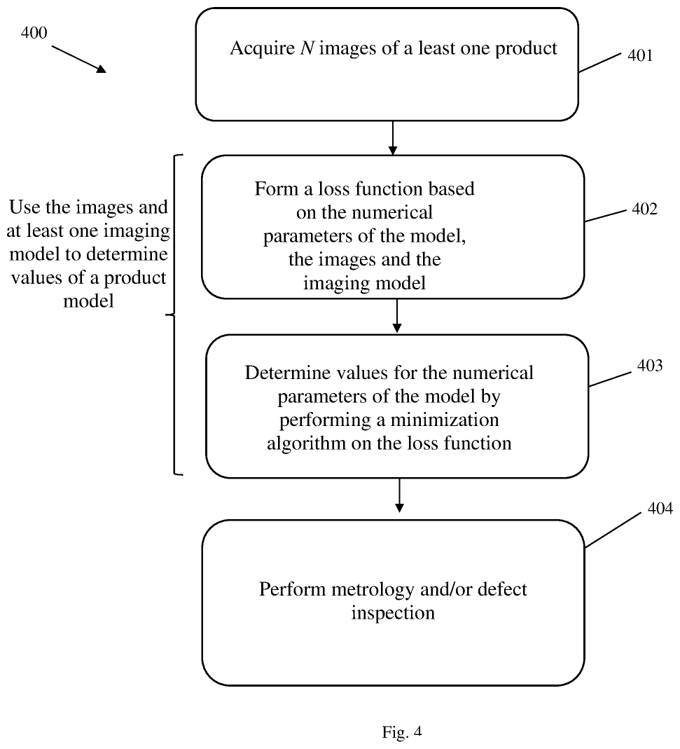

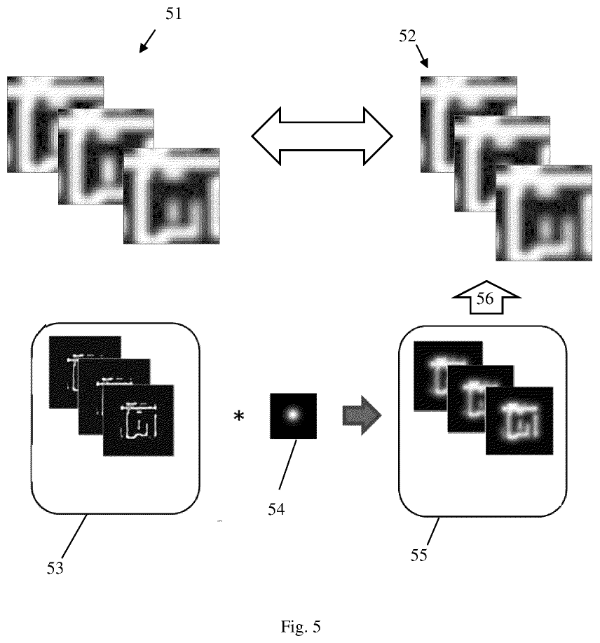

FIG. 4 shows the steps of a method 400 according to the invention. The application of this method to the inspection process of FIG. 1 will first be described with reference to FIGS. 5-9. It will then be discussed how the method 400 of FIG. 4 may be applied to perform the inspection task of FIG. 3.

The method 400 may be performed by a computer processor. In a first step 401 of method 400, N images are acquired of at least one product (e.g. received from an imaging unit which acquired the images by capturing them; for example, the imaging unit may be as shown in FIG. 1). The imaging process (or processes) used to capture the acquired images are described by an imaging model (or multiple corresponding imaging model(s)).

In steps 402, 403, the N images acquired in step 401 are used, in combination with the imaging model(s) of the imaging process(es) by which the N images were captured, to determine numerical values of a product model. Specifically, in step 402 a loss function is formed based on the numerical parameters of the product model, the acquired images and the imaging model(s). In step 403, the numerical parameters of the product model are determined by minimizing the loss function with respect to the numerical parameters of the product model (and optionally with respect to other parameters also, as described below).

In step 404, using the product model, it is determined whether the product model meets an anomaly criterion indicative of the presence of a defect. Optionally, the location of the defect on the at least one product may also be estimated. If a defect is detected, further metrology and/or defect inspection is performed. Alternatively or additionally, step 404 may include metrology (measurements) on the product model.

A first example of the application of the method 400 of FIG. 4 to the inspection task of FIG. 2 will now be considered. The two wafers 20, 21 of FIG. 2 are two different products, e.g. produced successively by successive performances of a wafer fabrication process. In step 401, low resolution bright-field images may be acquired, showing respective imaging areas. The acquired images are denoted {Pₖ}, where k is an integer index, k=1 . . . . N. FIG. 5 shows three of the acquired bright-field images as 51. The images 51 are blurred and have poor spatial resolution.

Each acquired image 51 is an n×n array of pixels, where n is an integer (for simplicity, square arrays of pixels are considered, but in variants the arrays need not be square), and each pixel is associated with a respective intensity value.

Each acquired image 51 may be of a respective imaging area on one of the wafers 20, 21 containing an identical (or similar) structure. For example, each acquired image 51 may be of a corresponding an imaging area including one of the structures 22, 23, 24, 25.

The product model in this example of method 400 may be a set of N images depicted in FIG. 5 as 53, having a one-to-one correspondence to the acquired images 51. Each image 53 is an m×m array of pixels where m is an integer, with each pixel being associated with an intensity value. The intensity values for all the images 53 collectively form the numerical values of the product model. The images 53 are referred to as “reconstructed” images. The reconstructed images are denoted {Xₖ}. They are not as blurred as the acquired images 51, and thus they have greater spatial resolution. Furthermore, m may be greater than n. The reconstructed images 53 may have a higher pixel resolution than the acquired images 51, in that a given distance on the product spans a greater number of pixels of the reconstructed images 53 than of the acquired images 51.

The imaging model in this case includes a convolution 54 which is assumed to be known, and which applies a blurring defined by a point spread function B, which is a two-dimensional array of values (kernel), followed by a pixel resolution reduction process 56 of reducing the pixel dimension to n×n. In other words, the N reconstructed images 53 are images such that, if they are convolved with the kernel B, resulting in N respective arrays 55 of convolved values (which may also have size m×m), and if the pixel dimension of the each of the arrays 55 is reduced to n×n to generate N images 52 resembling corresponding ones of the acquired images (i.e. by being blurred and having a lower spatial resolution). Here these N images 52 are referred to as “corrupted images”. Note that each of the corrupted images 52 corresponds to one of the acquired images 51, and is an image of the same imaging area on one of the products 20, 21.

In one simple form of the pixel resolution reduction process 56, m is a multiple of n (i.e. m=an where a is an integer), so that each pixel of the images 52 corresponds to a respective axa patch of pixels of the convolved arrays 55. Thus, to perform the pixel resolution reduction process 56, the intensity value of each pixel of each corrupted image 52 can be obtained as the average of the intensity of the corresponding patch of the convolved array 55.

A more sophisticated form of the process 56 is based on the observation that, due to the convolution 54, portions of the product which are slightly outside the imaging areas (i.e. the areas on the product imaged in the images 51) influence the images 51. For that reason, it is preferred the reconstructed images 53 are images of respective areas on the products 20, 21 which are slightly larger than, and include, the corresponding imaging area. In other words, the area of the product(s) depicted by each corresponding reconstructed image 51 is the imaging area of the corresponding acquired image 51, plus a margin area around the periphery of the imaging area, which may be about as wide as half the point spread function defined by the kernel B (e.g. if the amplitude of the kernel is substantially a Gaussian function of distance from a central position, the width of the margin may be in the range one to three standard deviations of the Gaussian function). In this case, the process 56 may include removing this margin from the arrays 55 of convolved values (which may be considered as applying a mask to the arrays 55), and then reducing the dimensionality of the result to be n×n.

The reconstructed images 53 may be thought of as intensity images which would be obtained if the imaging areas of the product (plus the margin areas) were imaged by a higher resolution imaging process than the one which produced the corresponding images 51.

In principle, a large number of possible sets of reconstructed images 53 have the property shown in FIG. 5 (i.e. the problem of using acquired images 51 to form reconstructed images 53 is ill-posed). However, this application of the method 400 makes use of the fact that there is some a priori knowledge about the reconstructed images 53. Firstly, the reconstructed images 53 are known to be limited in complexity, having a relatively small number of top-down features visible on the patterned stack. Also, the expected device structures have a smooth local variation (e.g. the patterned lines are formed out of material blobs and not sharp features). In addition, there are similarities between the reconstructed images 53 since their corresponding imaging areas contain the same structure or similar structures. This prior knowledge is used to define terms of a loss function as a function of the reconstructed images 53 (and of the acquired images 51 and the imaging model), such that minimizing the loss function with respect to the reconstructed images 53 ensures that the reconstructed images 53 are in accordance with this prior knowledge, and also match the measured data via the process exemplified in FIG. 5.

Specifically, the loss function may be of the form:

$$ℒ ( \{ {X}_{k} \} ) = {\sum }_{k} {‖ {MF}^{- 1} ( {FX}_{k} \cdot FB ) - {P}_{k} ‖}_{F}^{2} + α {\sum }_{k} {‖ [ {WX}_{k} ; {D}_{T V} {X}_{k} ; {X}_{k} ] ‖}_{1}^{1} + β {‖ [ {DX}_{1} , {DX}_{2} , … , {DX}_{N} ] ‖}^{*} \qquad ( 1 )$$

Here, the square brackets [ . . . ] denote the concatenation of the elements inside the bracket, M denotes the process 56, i.e. applying the mask and, where necessary, reducing the pixel dimension. F denotes a Fourier transform and F⁻¹ denotes an inverse Fourier transform. Pₖ denotes the k-th acquired image 51. Xₖ denotes the k-th reconstructed image 53. Thus, F⁻¹ (FXₖ·FB) denotes the array of convolved values 55 obtained by applying the convolution 54 to the reconstructed image Xₖ, and MF⁻¹ (FXₖ·FB) denotes the corrupted images 52. Note that the Fourier transform—i.e. the conversion from the spatial domain to the spatial frequency domain—is employed because it is a computationally efficient way of performing the convolution operation denoted by the kernel B, e.g. using a Fast Fourier transform (FFT) operation; in principle, the convolution operation can be implemented directly in the spatial domain, rather than by means of Fourier transforms. ∥·∥_{F}² denotes the Frobenius norm of a matrix, which is the squared l₂ norm of the matrix in a vector format. This quantifies the goodness of fit between the measurements and the reconstructed data.

Σₖ∥[WXₖ; D_{TV}Xₖ; Xₖ]∥₁¹ is a regularisation term, including a structural term DTVXk. W denotes a wavelet transformation (several wavelet transformations are known; the one used in the present experiments is a wavelet transformation based on the Haar wavelet). D_{TV} denotes a well-known operator which converts Xₖ into an image gradient domain. It uses nearby pixel differences (in the horizontal, vertical and/or diagonal directions) to encode this information. ∥·∥₁¹ is the l₁ norm, i.e. the sum of the absolution values. Here it is applied to [WXₖ; D_{TV}Xₖ; Xₖ] which denotes the concatenation of WXₖ, D_{TV} Xₖ and Xₖ.

D denotes an operation of converting a matrix Xₖ into a vector. ∥·∥* denotes a nuclear norm operation. The norm is computed as the sum of the absolute single values of the concatenation of all the vectorised images, i.e. [DX₁, DX₂, . . . , DX_{N}].

α and β are hyper-parameters, determining the relative importance of the terms in the loss function.

The minimisation algorithm can then be expressed as finding:

$$arg {min}_{\{ {X}_{k} \}} ℒ ( \{ {X}_{k} \} ) subject to 0 \leq {X}_{k} \leq M for all k and all points on {X}_{k} . \qquad ( 2 )$$

Thus, each point in Xₖ is constained to be in the range 0 to an upper pixel intensity limit M. The task of image recovery (i.e. obtaining the reconstructed images) can be stated as a deconvolution task with smoothness and low rank constraints.

Specifically, the term Σₖ∥MF⁻¹(FXₖ·FB)−Pₖ∥_{F}² encourages the corrupted images 52 to resemble the acquired images 51, i.e. it ensures data consistency. Note that Eqn. (1) formulates this property in the Fourier domain since it is easy to state the convolution task with the kernel B as a multiplication in the spatial frequency domain.

The regularization term Σₖ∥[WXₖ; D_{TV}Xₖ; Xₖ]∥₁¹ encourages Xₖ to include the expected features of the reconstructed images, such as areas with uniform intensity, and well-defined lines. The wavelet component WXₖ, and the component based just on Xₖ, encourage Xₖ to have a low fill ratio. The structural term D_{TV}Xₖ encourages the presence of edges. Optionally, to promote recovery of horizontal and vertical lines (on the assumption that the x and y axes in the images 51 are strongly correlated with elongation directions of elongate elements in the product), D_{TV} can be defined to give a higher weight in the vertical and horizontal directions than in diagonal directions. A step d can be introduced between pixels used in the computations (e.g. D_{TV} may be defined to compute the difference between horizontal/vertical pixels separated by a distance of d pixels where d is greater than one, rather than nearest-neighbouring pixels).

The term ∥[DX₁, DX₂, . . . , DX_{N}]∥* encourages the requirement that the images Xₖ are similar, since they are images of respective areas including similar structures (e.g. based on the same design data, or design data meeting a similarity criterion). This requirement is encoded in Eqn. (1) by ensuring that the concatenated reconstructed images produce a low-rank matrix. This property is encoded via a convex relaxation of the low-rank property, namely the nuclear norm∥[DX₁, DX₂, . . . , DX_{N}]∥*.

The hyper-parameters α and β may be chosen by trial-and-error, to produce reconstructed images 53 having the desired properties. For example, if high resolution images are available for certain products, e.g. an SEM tool, the hyper-parameters α and β can be chosen to ensure the best match with that image. Note that the setting of hyper-parameters α and β usually needs to be done only once in a “set-up” phase, so it is worthwhile incurring the costs of obtaining the high resolution image, so that the hyper-parameter values obtained can be used thereafter in the process of FIG. 5 for examining a large number of other products.

An equivalent formulation can be stated as a constrained optimization for the data fidelity part. That is, the loss function can instead by stated as:

$$ℒ ( \{ {X}_{k} \} ) = α {\sum }_{k} {‖ [ {WX}_{k} ; {D}_{T V} {X}_{k} ; {X}_{k} ] ‖}_{1}^{1} + β {‖ [ {DX}_{1} , {DX}_{2} , … , {DX}_{N} ] ‖}^{*} \qquad ( 3 )$$

With the minimisation being redefined as

$$arg {min}_{\{ {X}_{k} \}} ℒ ( \{ {X}_{k} \} ) subject to \{ \begin{matrix}0 \leq {X}_{k} \leq M for all k and all points on {X}_{k} \\ {\sum }_{k} {‖ {MF}^{- 1} ( {FX}_{k} \cdot FB ) - {P}_{k} ‖}_{F}^{2} \leq {ϵ}_{k}^{2}\end{matrix} \qquad ( 4 )$$

where ϵₖ are arbitrary small values, or may be chosen to match the noise statistics of the measured data. This allows for an easier definition of the cost function if the noise statistics are known for the measured data.

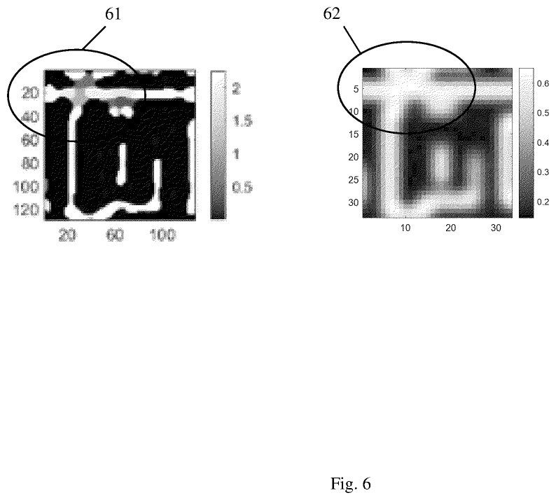

To test the method 400, acquired bright-field microscopy images were obtained from a real wafer fabrication process, each being composed of 32×32 pixels. The acquired brightfield images were from multiple locations on the wafer where the same patterns was intended to be printed (i.e. the structures in these imaging locations were based on the same GDS). Eqns. (3) and (4) were solved. FIG. 6 shows on the right one of the acquired images, including under-resolved features in the area 62. On the left is shown the corresponding reconstructed image, and in the area 61 corresponding to the area 62 super-resolved features are clearly visible.

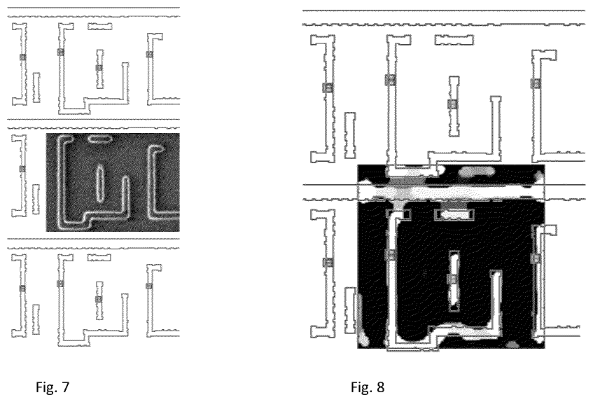

To check that the super-resolved features were not spurious, the GDS clip (i.e. the design data) for this location is shown in FIG. 7. FIG. 7 also shows, as an inset, measured high-resolution SEM data for the same GDS clip. FIG. 8 shows the reconstructed image overlapped with the GDS clip, showing clear agreement. This validates the ability of the embodiment to reconstruct the high-resolution image of the stack, especially since no information from the GDS was used in the reconstruction process.

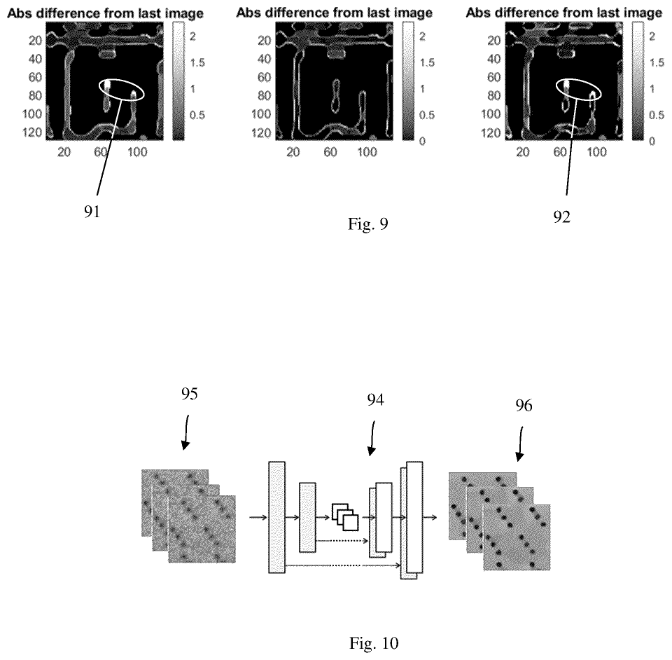

FIG. 9 shows pixel-to-pixel differences between several of the reconstructed images 53. FIG. 9 has three parts, each showing, as a brightness level, a difference between a corresponding pair of the reconstructed images. It will be seen that in the areas 91 and 92, the difference is high. This suggests that these regions in the structure are subject due to defects. In other words, an anomaly criterion has been defined based on the differences between reconstructed images corresponding to imaging regions of the product fabricated using the same design data.

The above technique has several possible applications. A first such application, as noted above, is as a measurement scheme for multiple locations (imaging regions) on one or more wafers, using acquired images of structures that are intended to be similar (e.g. have the same GDS design). These can be different locations (fields) on a single wafer (e.g. the locations 22, 23, 24 on FIG. 2), and/or the same corresponding location on multiple wafers (e.g. the locations 22, 25 on FIG. 2). As shown in FIG. 9, the structures in the different acquired images do not need to be exactly identical, i.e. we can tolerate process changes as long as they share the same overall features.

In a variation, the acquired images may all relate to the same imaging region on the wafer. Specifically, each of the N acquired images can be images obtained using a different set of imaging parameters (e.g. control parameters) cₖ in the imaging unit (sensor) which captured the acquired images. Each of set of imaging parameters cₖ may be accounted for by having a different imaging model for each k, e.g. by replacing the convolution kernel B in Eqns. (1)-(2), or Eqns. (3)-(4), with a convolution kernel Bₖ which depends upon the cₖ. The imaging parameters may include different sensor-to-target alignment conditions: slight movement of the sensor with respect to the target on the vertical and/or horizontal, sensor rotations with regards to the target (for example, if the plane of the surface of the wafer is the x-y plane, rotations about the z-axis; note that in this situation the rotation is accounted for in the imaging model, e.g. by varying D_{TV} for each k as well as the convolution kernel Bₖ), tilt (i.e. rotation about the x- and/or y-axes), an observation channel configuration (e.g. wavelength, focus, “dose” (linked to the power which reaches the sample), and exposure time, where again the different settings are quantified via a different convolution kernel Bₖ).

Note that this variation can be combined with the possibility of using multiple images from different imaging locations. That is, there may be multiple images, with different corresponding imaging parameters cₖ, from each of multiple locations on each of one or more products.

Another variation of Eqns. (1)-(2), or Eqns. (3)-(4), is in a continuous measurement scheme, in which the sensor is moving relative to the product when the images are recorded. Depending on the acquisition rate and the movement speed, the same target may be in the field of view for a number of acquired images. This allows for the scanning of a contiguous (continuous) region of the wafer, by defining a single reconstructed image which is based on multiple ones of the acquired images. That is, a reconstructed image may be of a contiguous region of the product (e.g. wafer) which spans the imaging regions for the multiple acquired images (i.e. it “stiches the imaging regions together”).

In all of these applications, in step 404 of the method 400 (of FIG. 4) the reconstructed (“super resolution”) images may be used to detect defects in the product(s) observed. Several options are possible to define an anomaly criterion for the presence of defects, such as: compare the super resolved image against the intended design and report significant deviations from the intended structure; and compare multiple images from positions where the same structure was intended and observe any deviations existing in a limited subset of the images. Once an anomaly has been detected, optionally, specialized low throughput tools (e.g. SEM) are the used for further inspection of the regions which meet the anomaly criterion.

Furthermore, for any of the applications, step 404 of the method 400 can include extracting metrology information, such as critical dimensions (CD) or overlay, by measurement of the reconstructed image(s), similar to the ways in which this is conventionally done from SEM measurement.

A number of variants of the above process will now be considered. A first variation is in a case in which imaging parameter(s) of the imaging processes(s) are not known, e.g. are only known to be in a certain range. Specifically, in one example, the kernel B is identified from the data.

This can be performed in two ways: (a) as a two-step procedure where a known target is imaged (possibly a target with a single feature that acts as a Dirac delta function in image domain), and B is estimated from the image; after this estimation the values for B can be used as in Eqns. (1)-(2) or (3)-(4); or (b) as a single step non-convex optimization task in which the minimization algorithm optimizes for the values B at the same time as solving for {Xₖ}. Specifically, the loss function can be revised as:

$$ℒ ( \{ {X}_{k} \} , B ) = {\sum }_{k} {‖ {MF}^{- 1} ( {FX}_{k} \cdot FB ) - {P}_{k} ‖}_{F}^{2} + α {\sum }_{k} {‖ [ {WX}_{k} ; {D}_{T V} {X}_{k} ; {X}_{k} ] ‖}_{1}^{1} + β {‖ [ {DX}_{1} , {DX}_{2} , … , {DX}_{N} ] ‖}^{*} + γ {‖ FB ‖}_{1}^{1} , \qquad ( 5 )$$

and the minimization algorithm of Eqn. (2) is reformulated as:

$$arg {min}_{\{ {X}_{k} \} , B} ℒ ( \{ {X}_{k} \} , B ) subject to 0 \leq {X}_{k} \leq M for all k and all points on {X}_{k} . \qquad ( 6 )$$

In addition to the previous constraints associated with the reconstructed images {Xₖ}, in this formulation the minimization algorithm is also searching for a B that is consistent with all the N observations (since it is a property of the imaging system). Typically, optical elements act as a low-pass filter so such properties can be encoded into the optimization task, one example being the property that B has a compact support, ∥FB∥₁¹, in Fourier domain, i.e. has a non-zero gain for a limited number of frequencies.

In the embodiments explained above, the image alignment of the acquired image 51 is assumed to be accurate (i.e. the corresponding structure on the product shown in each acquired image is at the same location in the acquired image). In some imaging systems, however, the image alignment between observations will be slightly different (though often by only a fraction of the pixel size in the acquired images). As such, in a second variation of the embodiment, the information content between two reconstructed images is (re-)aligned. One purpose of this is to enforce consistency properties between images, as the embodiment above aims to do using the low rank property defined by the nuclear norm. One way to correct for alignment shifts is by representing the shift of the k-th acquired image in the pixel domain as a phase shift matrix {Sₖ} in Fourier domain, and replacing the nuclear norm term in Eqn. (1) (or Eqn. (3)) with ∥[D\hat{X}₁, D\hat{X}₂, . . . , D\hat{X}_{N}]∥* where \hat{X}ₖ=F⁻¹ (FXₖ·Sₖ).

The matrices {Sₖ} can be found by an iterative approach in which the minimization algorithm of (2) (or Eqn. (4)) is solved several times with different realisations of the {Sₖ}. The initial {Sₖ} may be an identity mapping, and it is updated after every performance of the minimization algorithm for a better matching between the high-resolution images.

Alternatively, the matrices {Sₖ} can be obtained as a non-convex problem by treating the {Sₖ} as variables to be optimized in the minimization algorithm. This can be achieved by a change of variable, solving for {\hat{X}ₖ}, and {\hat{B}ₖ}, where each \hat{B}ₖ=Sₖ⁻¹·B. Note that the matrices {Sₖ} have a very specific structure, effectively each one depending on the known image dimensionality and two unknown shifts, over the two image axes. While in the image domain these shifts are necessarily discrete, due to the pixel grid, in the Fourier domain they can be considered as a continuous variable. The loss function then becomes:

$$ℒ ( \{ {\hat{X}}_{k} \} , \hat{\{ {B}_{k} \}} ) = {\sum }_{k} {‖ {MF}^{- 1} ( F {\hat{X}}_{k} \cdot F {\hat{B}}_{k} ) - {P}_{k} ‖}_{F}^{2} + α {\sum }_{k} {‖ [ W {\hat{X}}_{k} ; {D}_{T V} {\hat{X}}_{k} ; {\hat{X}}_{k} ] ‖}_{1}^{1} + β {‖ [ D {\hat{X}}_{k} , D {\hat{X}}_{k} , … , D {\hat{X}}_{k} ] ‖}^{*} + γ {‖ {FS}_{k} {\hat{B}}_{k} ‖}_{1}^{1} \qquad ( 7 )$$

and the minimization algorithm becomes:

$$arg {min}_{\{ {\hat{X}}_{k} \} , \{ {\hat{B}}_{k} \}} ℒ ( \{ {\hat{X}}_{k} \} , \{ {\hat{B}}_{k} \} ) subject to 0 \leq {X}_{k} \leq M for all k and all points on {X}_{k} \qquad ( 8 )$$

Many variations are possible within the scope of the invention. For example, although the embodiments explained above use acquired bright-field microscopy images {Xₖ}, the acquired images may alternatively be SEM measurements. Here the raw signal from the measured structure is observed by the SEM detector after passing through the different focusing systems in the SEM tool. This is akin to the low-pass filtering with an unknown filter kernel. Given this, there are similarities with the bright field metrology so the same data processing framework can be applied. Thus, acquired images coming from a fast SEM (optimized for speed and not accuracy) can be enhanced.

In another variation, only a subset of points in a field of view (imaging region) of an SEM tool may be measured. That is, the SEM tool may be configured to measure/excite only parts of the points from the field of view (given appropriate sampling: e.g. uniform random or pseudorandom), to thereby provide a faster measurement. In this instance the techniques presented above can be applied to fill in the missing information. This is possible since each observed signal (for example a SEM pixel of an acquired image) is a sample of the electron interaction in the device given a mixing, blurring kernel. As such each individual measured pixel contains information (is blurred) from the nearby structure.

Additionally, although the product model in the embodiment above is one which comprises reconstructed images {Xₖ}, the product model may alternatively be one in which structures of the products are defined geometrically, based on geometrical parameters, such as numerical values for lengths (dimensions) or angles in the product model. For examples, the product model may be defined based on a plurality of elements (e.g. all in one plane, or with different ones of the elements being in multiple spaced apart planes), and the geometrical parameters may comprise dimensions of the elements, and/or angles between directions defined by the elements and/or predetermined directions.

For example, consider again the product shown in FIG. 3, which contains R (e.g. six) elongate elements 33, 32, 31, 35, 36, 37. These elements may be labelled by r=1 . . . R. A product model may be defined in which each element has geometrical properties defined by a respective set (vector) of geometrical parameters gᵣ. The geometrical parameters gᵣ of the r-th element may for example include, in the case of an elongate element: a translational position of a point (e.g. a centroid) of the elongate element (e.g. a two-dimensional position in an x-y plane parallel to layers 34, 35, and a z-position in the direction in which the layers 34, 35 are spaced); a length of the elongate element; a width of the elongate element; an angle between the length direction of an elongate element in the product and a reference direction; or an angle between the respective length direction and the length direction of another elongate element in the product (e.g. an elongate element in another layer).

N images {Pₖ} of the product(s) may be acquired using different respective realisations {cₖ} of the set of imaging parameters. For a given realisation cₖ of the imaging parameters, the r-th element may produce a pattern of intensity in the image Pₖ which is given by a function ƒ(gᵣ, cₖ). Ignoring interaction between the elements, therefore, the corrupted image corresponding to acquired image Pₖ would be given by Σᵣƒ(gᵣ, cₖ).

A loss function may be defined which is:

$$ℒ ( \{ {g}_{r} \} ) = {\sum }_{k} {‖ {\sum }_{r} f ( {g}_{r} , {c}_{k} ) - {P}_{k} ‖}_{F}^{2} . \qquad ( 9 )$$

Values for the numerical parameters {gᵣ} may then be found by minimizing [symbol] ({gᵣ}) with respect to the numerical parameters {gᵣ}.

Here it is assumed, as part of the imaging model, that each of the R elements produces an independent pattern of intensity in each image Pₖ irrespective of the presence of the other elements. In a more sophisticated variant of this algorithm, the imaging model may take into account interactions between the elements, e.g. that elements in one layer of the product may partially occlude elements in the layer beneath. For this reason, the process of generating the corrupted images from the {gᵣ} may be performed using a numerical simulation. This information may be included in a more sophisticated version of the loss function of Eqn. (9).

In a further level of sophistication, the product model may include elements beside elongate elements 33, 32, 31, 35, 36, 37, such as elements having another shape, or elongate elements (e.g. such as vias) which extend in the z-direction.

In some implementations performing the above process (in particular the computational processing of the captured images described above with reference to steps 402 and 403 of FIG. 4) may be computationally time-intensive or computationally resource-intensive. For example, as described above, the method 400 may be implemented using an iterative approach in which the minimization algorithm of (2) (or Eqn. (4)) needs to be solved several times with different realisations of the {Sₖ}. Such an iterative approach may be computationally expensive. Further, the method 400 may generate more accurate values for the parameters describing the product model for larger values of N (i.e. for larger sets of images). Processing a larger set of images may increase the time or the computational resources needed to perform the method. Consequently, implementing the method 400 may require expensive computational hardware to achieve real-time processing, or alternatively take an undesirably long time for certain applications.

Thus, for some applications (for example where real-time processing is required) it can be desirable to provide a process that is computationally less expensive than the process 400 but which approximates the process 400 (or at least part of it, e.g. steps 402 and 403) sufficiently well to generate useful estimates of the numerical parameters defining the product model or images of the product which contain higher spatial resolution information than the captured images.

It is known for a deep learning neural network model to be used to perform image enhancement on an input image. For example, a neural network model may be trained to map a highly convolved image to corresponding deconvolved image, i.e. such a model may learn an approximation of a deconvolution task. The generated image may contain higher spatial resolution information than the (highly convolved) input image. To this end, neural network models may be trained using reference images that represent the same sample with different spatial resolutions (e.g. a low resolution image and high resolution image of the same sample may be provided to the model during training). However, frequently such reference images are unavailable, or very expensive to acquire. For light-based imaging tools (e.g. brightfield microscopes), an image with “high spatial resolution” may not obtainable since the achievable resolution (limited e.g. by the properties of the employed light) may be too low to resolve the features of the product of interest. For scanning electron microscope (SEM) tools, data with high resolution measurement is generally slow to acquire or is affected by high noise levels. Furthermore, the images may not be available due to confidentiality concerns. Furthermore, neural network models trained on acquired reference data may not generalize well for other use cases (e.g. products with substantially different geometric features), and new, use-case-specific reference data may be needed. It is therefore desirable to provide a process of training a neural network that encourages the neural network to learn an approximation of a deconvolution task without requiring acquired high resolution images during training. Such a process (and a corresponding system) are described below with reference to FIGS. 10 to 15.

In overview, a training dataset is created by computationally performing image enhancement on a number of acquired images. For example, images of high spatial resolution may be computationally generated from acquired low resolution images by using, for example, the above process 400 or any other suitable computational method. The generated high resolution images and the acquired low resolution images can then be used as training data to train a neural network such that the neural network generates from a low resolution input image an output image that (closely) matches the corresponding generated high resolution image. Once trained, the neural network can be deployed to perform the learned image enhancement task, i.e. to generate high resolution images from low resolution input images. Because the high resolution training images are generated via a computational process, there is no need to acquire high resolution reference images for training of the neural network.

In some instances, where the acquired (low resolution) training images are a set of images representing the same (or similar) structure (as in process 400 described above), the trained neural network models may perform the image enhancement task several orders of magnitude faster than the computational process used to generate the high resolution training data. This is because by providing only training images of the same (or similar) structure the neural network is not encouraged to learn a “generic image enhancement task” (i.e. a process that can successfully be applied to images representing a broad range of structures) but rather a image-to-image mapping specific to a specific product structure (e.g. products of a single fabrication process), so that it can successfully enhance images of the same (or similar) structure that was used to create the training dataset.

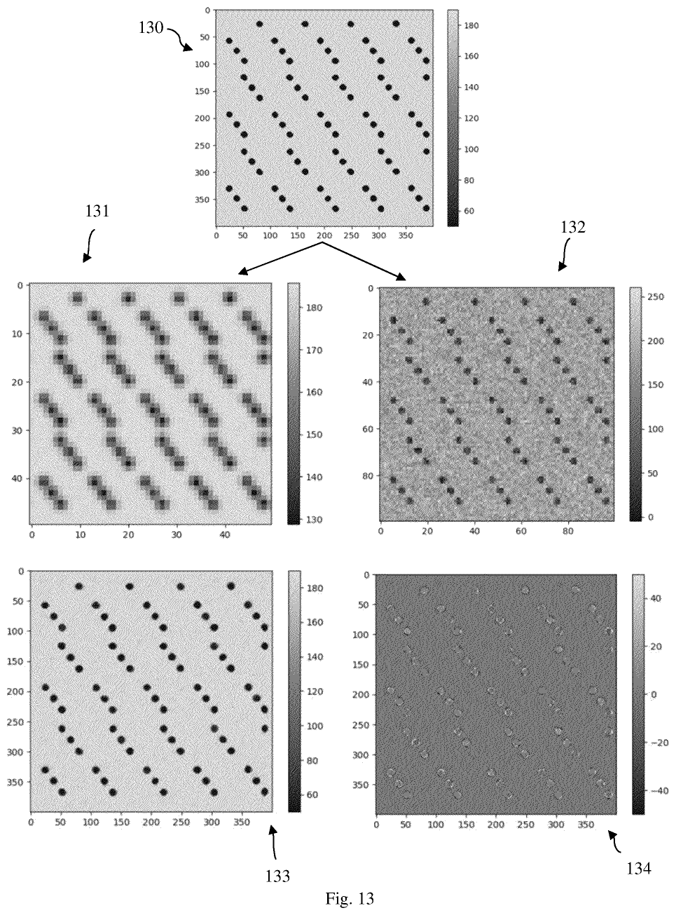

Referring FIG. 10, a schematic illustration is shown of a neural network 94. The neural network 94 has a plurality of network parameters and is configured to receive an input image and to process the input image in accordance with the network parameters to generate an output image. In particular, the neural network 94 is configured to perform an image enhancement task, e.g. generating a high resolution image from a low resolution input image. Suitable values for the network parameters may be determined by performing a training process as described below with reference to FIG. 12. The neural network 94 comprises a convolutional neural network, having for example the known “U-Net” structure (Ronneberger O, Fischer P, Brox T (2015). “U-Net: Convolutional Networks for Biomedical Image Segmentation”. arXiv: 1505.04597), as shown in FIG. 10, or the like. It is understood that other model architectures can be used, for example an (variational) auto-encoder. Generally, any neural network model that can perform image-to-image mapping may be suitable. A system of one or more computers located in one or more locations may be used to implement the neural network 94.

The neural network 94 is configured to receive as input an image (i.e. a two-dimensional array of intensity values). FIG. 10 shows three input images 95 which may be (sequentially) provided to the neural network 94. The input images 95 shown in FIG. 10 are acquired using a SEM tool. In other embodiments, the input images may be acquired with another tools, for example with a brightfield imaging tools or dark field imaging tool.

The image provided (as input) to the neural network 94 may be an image of a product of a fabrication process, e.g. a semiconductor product fabricated on a wafer. The example images 95 of FIG. 10 show a pattern of holes. In general, the input image to the neural network 94 may be an image that has been captured by performing an imaging process on an imaging area on one of the wafer. In the same manner as described above for the acquired images for use in process 400, also the imaging process to capture the input image to the neural network 94 is performed by an imaging device and may be characterized by at least one imaging parameter. In an embodiment, the at least one imaging parameter may specify a configuration of the imaging device. In broad terms, the input image provided to the neural network 94 are typically of insufficient image quality, e.g. the image does not sufficiently resolve some details of the imaged product. In other words, the input image may have a low spatial resolution. For example, the example input images 95 are so noisy that the hole pattern is only poorly resolved.

The neural network 94 is configured to process the input image (in accordance with the network parameters) to generate a reconstructed image that has a higher resolution than the input image. Thus, the generated image may contain higher spatial resolution information than the input image. For example, the neural network may process the example input images 95 to generate the high resolution output images 96. The hole pattern is better resolved in the output images 96 than in the input images 95. For clarity it is noted that, whilst FIG. 10 shows three input and three output images, the neural network 94 may process each input image 95 separately (i.e. independently of the other input images 95) to generate a corresponding high resolution image 96.

In an embodiment, the neural network 94 is further configured to receive as input (in addition to the input image) the at least one imaging parameter characterizing the imaging process used to capture the input image. In this embodiment, the neural network 94 may be configured to process the input image and the at least one imaging parameter to generate a reconstructed image that has a higher resolution image than the input image.

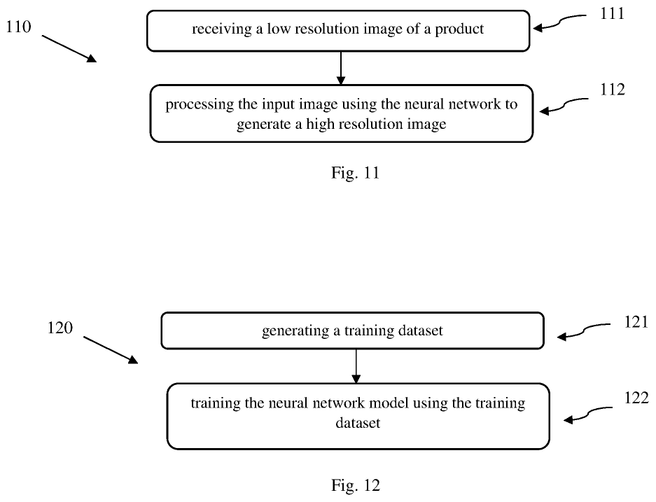

FIG. 11 shows a flow diagram of an example process 110 of processing an image with the neural network 94 to generate a reconstructed image that has a higher resolution image than the input image. In step 111, an input image (with low spatial resolution) is received. In an embodiment, the at least one imaging parameter characterizing the imaging process used to capture the input image is also received in step 111. In step 112, the neural network 94 processes the input image to generate a reconstructed image that has a higher resolution image than the input image. In an embodiment where the at least one imaging parameter is provided to the neural network 94, the neural network 94 processes the input image and the at least one imaging parameter to generate a reconstructed image that has a higher resolution image than the input image.

FIG. 12 shows a flow diagram of an example process 120 of training the neural network 94. In general, the neural network 94 is trained with a training dataset comprising a plurality of training item. Each training item comprises an acquired image of a training object and a corresponding computationally generated image that contains higher spatial resolution information than the acquired image.

In step 121, a training dataset is generated. To this end, a plurality of training images is captured by performing an imaging process on imaging regions of corresponding training object(s) (e.g. the same training object for all the training images, or respective training objects for each training image). The training objects are substantially identical. For example, each of the training objects may be a product of a fabrication process (e.g. a semiconductor product fabricated on a wafer like the products described above with reference to FIGS. 2 and 3) which has been fabricated according to the same design data, e.g. the training objects were intended to be identical but may differ to some extent due to fabrication defects or any other (accidental) variation in the fabrication process.

In an embodiment, each training item of the training dataset may further comprise imaging parameter(s) characterizing the imaging process used to capture the corresponding image of the respective training item.

Further in step 121, a computational method is applied to the plurality of acquired training images so as to reconstruct a corresponding plurality of high resolution training images (i.e. the reconstructed images contain higher spatial resolution information than the acquired training images).

In an embodiment, the plurality of high resolution training images is reconstructed by performing steps 402 and 403 of process 400 (as described above) and generating the reconstructed images based on the determined values of the product model.

In another embodiment, a variation of the above described computational method (i.e. steps 402 and 403 of process 400) may be applied where each acquired training image is processed separately. For example, for each acquired training image a high-resolution image X may be found by solving an optimization task

$$arg {min}_{X} {‖ {MF}^{- 1} ( FX \cdot FB ) - P ‖}_{F}^{2} + α {‖ [ WX ; {D}_{TV} X ] ‖}_{1}^{1} \qquad ( 10 )$$

$$s . t X \geq 0 , X \leq m$$

where the symbols have the meaning described above with reference to Eq (1), i.e. P is the respective acquired image, B is the kernel (representing for example a point spread function of the imaging device), W and D_{TV} are linear operators, M denotes applying a mask (and, where necessary, reducing the pixel dimension), F denotes a Fourier transform and F⁻¹ denotes an inverse Fourier transform. As before, the term ∥MF⁻¹ (FX·FBᵢ)−P∥_{F}² ensures data consistency.

In another embodiment, a further variation of the above described computational method (i.e. steps 402 and 403 of process 400) may be used. In this embodiment, a set of images (e.g. two images) of the same object are collectively processed to generate a corresponding high-resolution image. Each of the images in the set may be acquired using different imaging modalities (for example a first image may be acquired with low spatial resolution and a low noise level, and a second image acquired with high spatial resolution and a high noise level). This embodiment may be particularly useful for integrated circuit inspection/metrology based on SEM imaging where it is frequently observed that acquiring image data using a SEM requires a trade-off between speed, resolution and accuracy. Acquiring an SEM image with a low energy (applied to the primary electron beam) may result in a high spatial resolution but may also result in a low signal to noise ratio (as well as a slow measurement speed). On the other hand, acquiring an SEM image with a high energy may increase the measurement speed and the signal to noise ratio at the expense of the spatial resolution (due to a large interaction volume, i.e. a large volume of the sample that the incoming electrons are interacting with). To illustrate this, FIG. 13 shows in panel 131 a first, low resolution (and low noise) input image of a hole array structure and in panel 132 a second, high resolution (but noisy) input image of the same structure (the images in panels 131, 132 are not acquired images but computationally generated for the purposes of illustration from the “ground truth” image shown in panel 130).

Further in this embodiment, a high resolution image (e.g. panel 133 of FIG. 13) may be reconstructed by performing a deconvolution task such that the high resolution image is consistent with the (information comprised in the) first and the second input image (e.g. panels 131, 132 of FIG. 1). Similar to the method described with reference to Eq. (1), also in this embodiment images of different instances of the same structure may be processed together to improve the deconvolution result. In particular, a plurality of sets of images (i.e. images within each set are images acquired with different modalities, and each set represents a different instance of the same structure) may be processed together to find a corresponding high-resolution image Xₖ for each input set by solving an optimization task

$$arg {min}_{X} {\sum }_{k , i} {‖ {M}_{i} {F}^{- 1} ( {FX}_{k} \cdot {FB}_{i} ) - {P}_{k , i} ‖}_{F}^{2} + α {\sum }_{k} {‖ [ {WX}_{k} ; {D}_{TV} {X}_{k} ; {X}_{k} ] ‖}_{1}^{1} + β {‖ [ {DX}_{1} , {DX}_{2} , ... , {DX}_{N} ] ‖}^{*} \qquad ( 11 )$$

$$s . t {X}_{k} \geq 0 , {X}_{k} \leq m , ∀ k$$

where the symbols have the meaning described above with reference to Eqs. (1) and (10) except that, to enable the use of different imaging modalities, multiple Kernels Bᵢ are used (each corresponding to one of the modalities. Similarly, P_{k,i} represents an acquired image where the index k indicates a particular set and the index i indicates the imaging modality. As before, W and D_{TV} are linear operators, M denotes applying a mask (and, where necessary, reducing the pixel dimension), F denotes a Fourier transform and F⁻¹ denotes an inverse Fourier transform. The term ∥MᵢF⁻¹ (FXₖ·FBᵢ)−P_{k,i}∥_{F}² ensures data consistency. It is understood that Eq. (11) can also be performed for a single input set (thus in this case no summation over k is required in Eq. 10).

Panel 133 shows a high resolution image found by using Eq. (11) for the input images 131, 132 of FIG. 13. It is evident that the reconstructed image 133 strongly resembles the ground truth 130. This is further illustrated by panel 134 which shows that a difference between panels 130 and 133 is small. Thus the reconstructed image 133 has a high spatial resolution and a low noise level. The method described with reference to Eq. (11) may be used to perform step 121, i.e. to computationally generate from the plurality of acquired training images a corresponding plurality of high resolution training images. In this case, as described above, the plurality of training images comprises sets of acquired images where the images within each set are acquired using a different imaging modality.

Whilst the method described above with reference to Eq. (11) has been illustrated with high and low resolution SEM images, it is understood that the set of imaging modalities is not limited to these examples.

In general, any computational (deconvolution) method that performs an image enhancement task (i.e. that generates a reconstructed image containing higher spatial resolution information than the acquired input image) may be used to generate the reconstructed images for the training data set. For example, the computational method may be implemented using a further neural network model.

In step 122, the neural network 94 is trained using the training data set. In particular, for each training item of the training dataset, the neural network 94 receives (as input) the acquired image of the respective training item and processes the input image to generate (as output) a reconstructed image. The output image is then compared to the corresponding (computationally generated) high resolution training image of the respective training item to determine a discrepancy between the output image and the high resolution training image. The network parameters are then adjusted so that the discrepancy is reduced. In other words, the network parameters of the neural network 94 are updated so that the neural network 94 processes the acquired images to generate an output image that (substantially) matches the corresponding (computationally generated) high resolution training image. It is understood that several known methods can be used to implement step 122 (e.g. backpropagation and gradient decent based optimization algorithms), i.e. to determine the network parameters based on discrepancies derived from the training items.

In an embodiment where each training item comprises the at least one imaging parameter characterizing the imaging process used to capture the corresponding image of the respective training item and the neural network 94 is configured to receive the at least one imaging parameter as further input (in addition to the input image), for each training item, the network parameters are adjusted based on the discrepancy between the output image and the corresponding high resolution training image and based on the corresponding at least one imaging parameter.

In an embodiment where step 121 of FIG. 12 is performed according to the method described with reference to Eq. 10 and FIG. 13, the neural network 94 may be configured to receive as input a set of acquired images where the images are acquired with the same set of imaging modalities that are used to generate the training images (for example images 131 and 132 of FIG. 13 may be provided as input to the neural network 94). Alternatively, the neural network 94 (trained on high resolution images generated according to the method described with reference to Eq. 10 and FIG. 13) may be configured to receive as input only images acquired with one of the imaging modalities (e.g. only low resolution, low noise images).

In general, once trained, the neural network 94 can be used to process an input image to generate a reconstructed image that has a higher resolution image than the input image (as described above with reference to FIG. 11). Because the images comprised in the training dataset relate to the same (or similar) object, the neural network learns a specific image-to-image mapping that can successfully enhance the images of the same (or similar) object that was used to create the training dataset. As a consequence, the use of the trained neural network 94 can be computationally lightweight compared to the computational method used to create the high resolution training images. Thus, while the generation of the training dataset may be computationally expensive, once trained (and deployed) the neural network 94 can process images fast and without requiring large computational resources (e.g. fast enough to allow real-time application). In other words, in the above method and system, computationally expensive tasks are effectively front-loaded into the training phase so that the system is computationally lightweight during deployment.

Once trained, the neural network 94 may be used to process images of similar objects as the ones represented in the training dataset. The output images of the neural network 94 may be used for defect inspection. If the input image represents an object which differs from the training objects more than a certain degree, the neural network 94 may not perform the image enhancement task well, i.e. in this case the generated output image may be (substantially) different from the reconstructed image that the computational method (used to generate the high resolution training images) would generate from the input image. Generally, the accuracy of the image enhancement task performed by the neural network 94 may be worse the larger a difference between the object represented in the input image and the training object(s) is. In other words, the trained neural network 94 may be employed for images showing objects which are similar to the training objects, and may need to be re-trained if the neural network 94 is to be used with images showing substantially different objects.

In an embodiment where the respective imaging parameters are not provided (as further input) to the neural network 94 during training and deployment, the accuracy of the image enhancement task performed by the neural network 94 may be worse if the imaging process used for the input image during deployment is (substantially) different from the imaging process used to acquire the training images. In an alternative embodiment where the respective imaging parameters are provided (as further input) to the neural network 94 during training and deployment (and the training images were acquired over a broad range of different imaging parameters), the accuracy of the image enhancement task performed by the neural network 94 may not be worse if the imaging process used for the input image during deployment is different from the imaging process used to acquire the training images. This is because the neural network 94 (during training) may have learnt to distinguish the effects on the input image caused by the imaging process from effects caused by the object represented in the input image. In this case, when the trained neural network 94 receives imaging parameters which have not been included the training dataset, the neural network 94 may effectively interpolate to account for the effects caused by the imaging parameters on the input image.

Some benefits of the neural network 94 may be understood by considering an example workflow. A first semiconductor wafer may comprise multiple structures formed by fabrication process. The structures may have been indented to be identical (i.e. they have been fabricated according to the same design data). An imaging device may be used to acquire low resolution images of the structures of the first wafer. These images can then be used to create the training dataset for the neural network 94. This means that these images can be used to create (possibly in a computationally expensive way) reconstructed, high resolution images of the structures of the first wafer. The neural network 94 is then trained on the training dataset. When successive wafers are fabricated (i.e. wafers fabricated according to the same design data as the first wafer), the imaging device may be used to acquire low resolution images of the structures of these successive wafer, from which the neural network 94 can generate high resolution images, for example for defect inspection. Because the processing images with the trained neural network 94 is computationally lightweight, the neural network 94 can enable fast (e.g. real-time) defect detection and can therefore improve the operation of the fabrication process.

Whilst the neural network 94 has been described in the context of defect detection of semiconductor products, it is understood that the neural network 94 can be used for a broad range of application.

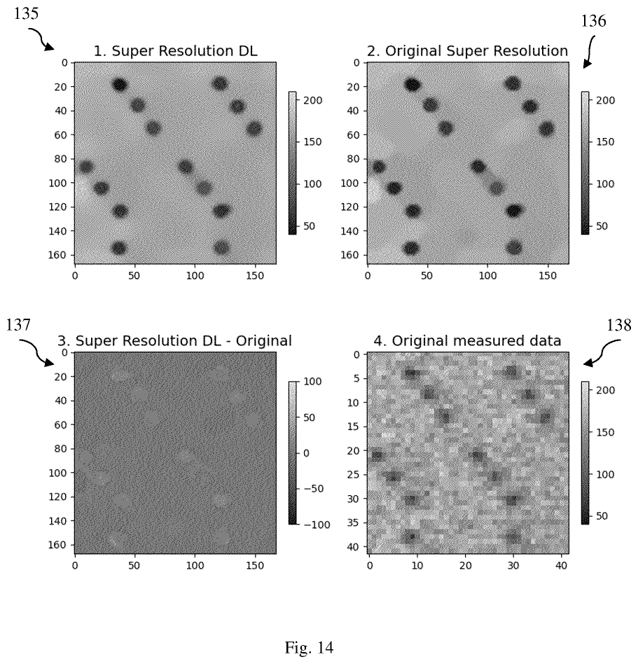

Experimental results obtained with an example neural network trained according to the method FIG. 13 are described below with reference to FIGS. 14-16. The example neural network is model with a “U-Net” structure. The training dataset includes 500 (low resolution) SEM images showing a particular hole pattern and correspondingly 500 high resolution images that have been computationally generated based on the optimization task described above with reference to Eq. 10. This training dataset was used to train the example neural network.

Panel 138 of FIG. 14 shows, as an example, one acquired SEM image. Panel 135 of FIG. 13 shows the corresponding output image of the trained neural network. The hole structure is clearly better resolved in the output image 135 than in the acquired image 138. To illustrate the accuracy of the neural network, FIG. 14 shows also the high resolution image reconstructed using Eq. (10) in Panel 136 and further, in panel 137, the difference between panels 135 and 136. The images in panels 135 and 136 are substantially identical and the difference between them (as shown in panel 137) is small. Thus, the trained neural network is to able effectively replicate the results obtained by performing the deconvolution using the optimization formulation of Eq. 10.

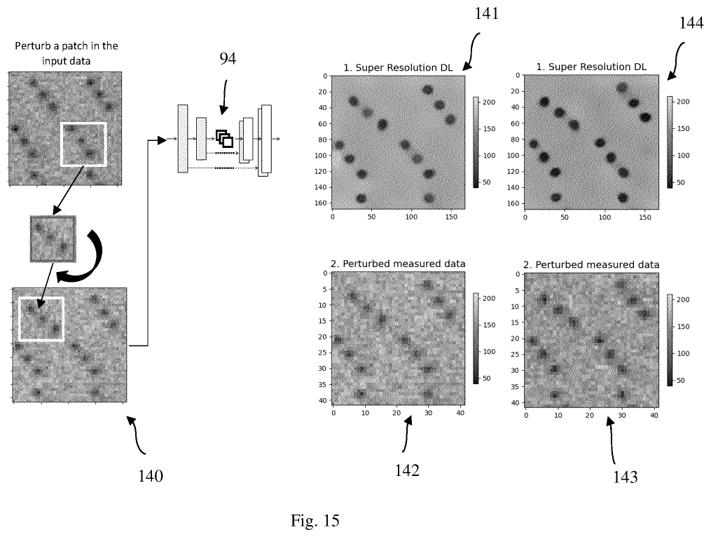

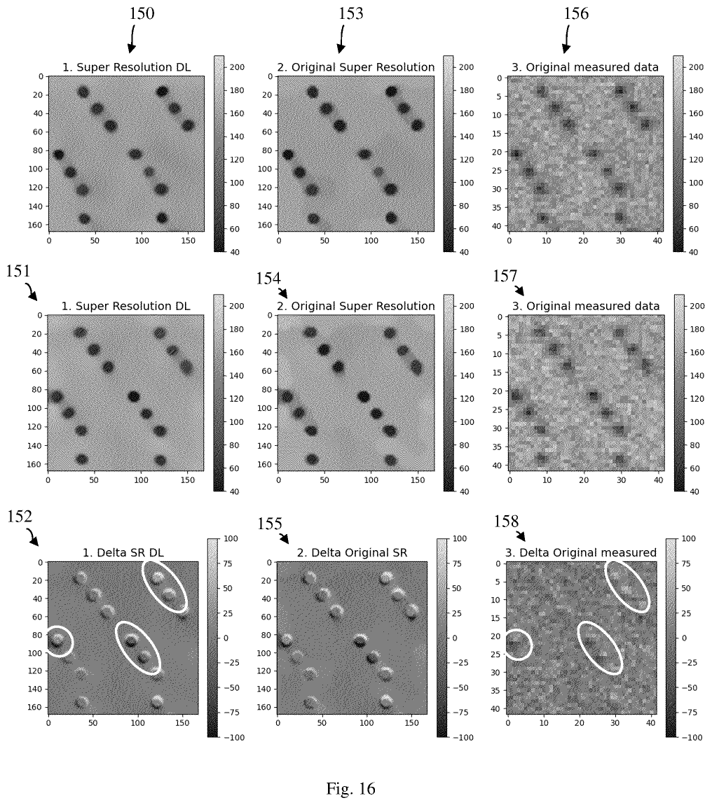

FIG. 15 illustrates that the trained neural network is able to work well even if the structure shown in the input image difference (slightly) from the structures shown in the training images. To this end, synthetic examples of images of different structures are created by perturbing a test input image. In particular, to create such a synthetic example 140, a copy of a region of a test input image is rotated and inserted into another region of the test input. Panels 142 and 143 show two of such synthetically generated images, and panels 141 and 144 show the corresponding output images of neural network. Panels 141 and 144 show the altered hole structure with high resolution, demonstrating that the neural network can perform image enhancement also on images that represent structures which are different from the training structures.

FIG. 16 illustrates the usefulness of the neural network 94 for defect inspection. In the case where no ground truth information about how the structure should look like is available (e.g. because this information may be proprietary to another party), defect inspection can be based on detection differences between samples (typically there will be many sample which have been correctly manufactured and a smaller number which have defects). Panels 156 and 157 of FIG. 16 show acquired SEM images of two imaging portions of a wafer. The structures in these two portions have been fabricated with the intention to be identical. Panels 150 and 151 show the corresponding output images of the neural network, and, for comparison, panels 154 and 154 show the images obtained by performing the deconvolution using the optimization formulation of Eq. 10. As mentioned above, a difference between the structures of the two imaging portion may be indicative of a defect. Panels 152, 155 and 158 show respectively the difference between panels 151 and 152, 154 and 155, and 157 and 158. The fact that panels 152 and 155 are almost identical shows that the output images of the neural network are as useful for defect inspection as the images obtained by performing the deconvolution using the optimization formulation of Eq. 10. Further, comparing panel 152 and 158 shows that the output images of the neural network reveal difference in the two imaging portions that are barely visible in the original data.

Further embodiments of the present invention are presented in below numbered clauses:
1. A method for obtaining information describing at least one product of a fabrication process, the method comprising: acquiring a plurality of images, the images having been captured by performing an imaging process on one or more corresponding imaging regions of the at least one product; and using the images and at least one corresponding imaging model characterizing the imaging process, to determine values for plurality of numerical parameters which collectively define a product model of a portion of the at least one product, the determination of the values including:
forming a loss function based on the plurality of acquired images, the at least one imaging model, and the numerical parameters of the product model; and
determining values for the numerical parameters of the product model by performing a minimization algorithm on the loss function with respect to the numerical parameters.
2. A method according to clause 1 in which the determination employs a loss value indicative of a difference between the images and a result of applying the at least one corresponding imaging model to the corresponding imaging regions of the product model.
3. A method according to clause 2 in which the loss function includes the loss value as a loss term.
4. A method according to clause 2 in which the minimization algorithm is performed subject to a constraint on the loss value.
5. A method according to any of clauses 2 to 4 in which the loss value is a sum over the images of, for each image, a measure of a difference between the image and a corresponding estimated image obtained by applying the corresponding imaging model to the corresponding imaging region of the product model.
6. A method according to any preceding clause in which the imaging process is performed by an imaging device and is characterized by at least one imaging parameter, and the plurality of images include multiple images of a single said imaged region of a single said product, captured by the imaging process with different respective realisations of the at least one imaging parameter, the determination of the values of the numerical parameters employing a different corresponding said imaging model for each realisation of the at least one imaging parameter.
7. A method according to clause 6 in which the imaging parameters include at least one imaging parameter selected from the group consisting of:
   a distance of a sensor of the imaging device from the at least one product;
   an orientation of the at least one product with respect to an imaging direction in which the images are captured in the imaging process;
   a translational position of the at least one product transverse to an imaging direction in which the images are captured in the imaging process;
a focal position of the imaging device relative to the product; and
an exposure time used in capturing the image.
8. A method according to any preceding clause in which the imaging model comprises a convolution model based on an array of values indicative of the values of respective points of a point spread function.
9. A method according to any preceding clause in which the model of the at least one product includes at least one two-dimensional array of values indicative of a brightness of corresponding points of the product according to a further imaging process.
10. A method according to clause 9, when dependent upon clause 8, in which the at least one two-dimensional array of values corresponds to points of the product spanning a larger area of the product than the imaging areas, the imaging model comprising applying the convolution model to the two-dimensional array of values to form convolved values, and applying a mask to limit the convolved values to the imaging area.
11. A method according to clause 9 or clause 10, in which the two-dimensional array of values has a pixel resolution which includes more intensity values per unit area of the product than the acquired images, the imaging model comprising a resolution-reduction model to reduce the pixel resolution of the two-dimensional array of values to a pixel resolution of the acquired images.
12. A method according to any of clauses 9-11, in which the loss function includes at least one regularization term based on a norm of the intensity values.
13. A method according to clause 12 in which the at least one regularization term includes a structural term which encourages the formation of edges in the two-dimensional array of intensity values.
14. A method according to clause 12 or 13 in which the regularization term is based on transform values obtained by applying at least one transform to the two-dimensional array of intensity values.
15. A method according to clause 14 in which the at least one transform comprises a wavelet transform and/or a transform which obtains image gradients in the two-dimensional array of values.
16. A method according to clause 14 or 15 in which the regularization term is a sum over the transform values of a function of each transform value.
17. A method according to any of clauses 9 to 16, further comprising measuring distances between at least one pair of points in the at least one two-dimensional array of values, to obtain a measured dimension of the at least one product.
18. A method according to any preceding clause in which the at least one imaging model is defined by one or more corresponding imaging parameters, the method further comprising obtaining values for the one or more imaging parameters of the at least one imaging model.
19. A method according to clause 18, when dependent upon clause 8, in which the one or more imaging parameters comprise the array of values indicative of the values of respective points of a point spread function.
20. A method according to clause 18 or 19 in which the one or more imaging parameters comprise control parameters of the imaging process.
21. A method according to any of clauses 18 to 20, wherein the minimization algorithm minimizes said loss function additionally with respect to at least some of the imaging parameters, thereby determining values for the at least some imaging parameters.
22. A method according to any of clauses 18 to 21, including acquiring a reference image captured by the imaging process of a target having a known geometry, and determining at least one of the imaging parameters based on the reference image and the known geometry.
23. A method according to clause 22 in which the target includes an object having a diameter less than a resolution level of the imaging process and located on a uniform background, the at least one of the imaging parameters being derived by treating the reference image as a point spread function of the object.
24. A method according to any preceding clause in which the loss function includes a plurality of terms multiplied by corresponding hyper-parameters, the method comprising selecting values for the hyper-parameters by performing the method repeatedly for different corresponding trial values of the hyper-parameters, and selecting the values for the hyper-parameters from the trial values of the hyper-parameters using a selection criterion based on at least one of (i) the corresponding determined values of the numerical parameters, and (ii) corresponding values the terms of the loss function following the minimization process.
25. A method according to any preceding clause in which the numerical parameters of the product model define respective geometrical parameters of the at least one product.
26. A method according to clause 25 in which the numerical parameters include numerical parameters which respectively indicate one of:
a position of an elongate element in the product;
a length of an elongate element in the product;
a width of an elongate element in the product;
an angle between the length direction of an elongate element in the product and a reference direction; or an angle between the respective length directions of two elongate elements in the product.
27. A method according to clause 25 or clause 26 in which the at least one product includes a plurality of layers spaced apart in a depth direction, and the numerical parameters include numerical parameters which respectively indicate one of:
a translational offset transverse to the depth direction of two structures in the at least one product in different respective said layers;
an angular offset transverse to the depth direction of the respective length directions of two elongate structures in the at least one product in different respective layers; or
a spacing in the depth direction between two structures in the product.
28. A method according to any preceding clause in which the images are optical images obtained by bright-field microscopy.
29. A method according to clause 28 when dependent upon clause 7 in which the imaging parameters include a frequency of electromagnetic radiation used in the bright-field microscopy.
30. A method according to any of clauses 1 to 27 in which the imaging process is scanning electron microscopy (SEM) and the images are scanning electron microscope SEM images.
31. A method according to any preceding clause further comprising determining whether at least one anomaly criterion is met in respect of any of the one or more imaging regions based on the determined values of the numerical parameters.
32. A method according to clause 31 in which, upon determining that the anomaly criterion is met in respect of any of one or more imaging regions, a further measurement is performed of the imaging regions in respect of which the anomaly criterion is met.
33. A method according to 31 or 32 in which determining whether the anomaly criterion is met comprises comparing the determined values of the numerical parameters to design data describing the at least one product, and determining the existence of a defect in the at least one product based on the comparison.
34. A method according to any preceding clause in which the images are of multiple imaging regions on the at least one product, each imaging region containing a corresponding structure produced by the fabrication process according to the same design data, the product model comprising a respective model portion for each of the imaging regions, each model portion being defined by a respective subset of the numerical parameters.
35. A method according to clause 34 in which the loss function comprises a discrepancy term which penalises differences between the model portions.
36. A method according to clause 35 in which the discrepancy term is a term which penalizes the rank of a concatenation of the numerical parameters defining the model portions.
37. A method according to clause 36 in which the discrepancy term is a nuclear norm of a concatenation of the numerical parameters defining the model portions.
38. A method according to any preceding clause further comprising registering the images to bring corresponding portions of the images into alignment.
39. A method according to clause 38, in which the registration is based on respective displacement vectors associated with the images.
40. A method according to clause 39, in which the displacement vectors are determined during the minimization process.
41. A method according to any preceding clause in which in the at least one product different ones of the imaging regions overlap, the different imaging regions thereby forming a contiguous enlarged imaging region.
42. A method according to any preceding clause in which the step of forming the loss function is performed repeatedly for different respective subsets of the imaging regions, and the step of determining values for the numerical parameters of corresponding model portions of the product model is performed for each subset, a defective one of the imaging regions being identified as an imaging region for which the value of the loss function following the minimization process is lower for subsets which omit the defective imaging region than for subsets which include the defective imaging portion.
43. A method according to any preceding clause which is performed repeatedly following repeated performances of the fabrication process, each performance of the method being performed on a product of the most recent performance of fabrication process.
44. A method according to clause 43 in which in each performance of the method the at least one product includes the product of the most recent performance of fabrication process and a product of a preceding performance of the fabrication process.
45. A method according to any preceding clause in which the fabrication process is a wafer fabrication process and the at least one product is a fabricated wafer.
46. A method according to clause 45 in which the fabrication process is a lithographic process.
47. A computing system comprising a processor and a memory, the memory storing program instructions operative, upon being performed by the processor to cause the processor to perform a method according to any preceding clause.
48. A computer program product storing program instructions operative, upon being performed by the processor to cause the processor to perform a method according to any of clauses 1 to 46.
49. A method of measuring at least one product of a fabrication process, the method comprising:
   imaging the at least one product using an imaging system by an imaging process characterized by at least one imaging parameter, wherein an imaging unit of the imaging system captures multiple images of at least one imaging region of the at least one product for multiple different corresponding realisations of the at least one imaging parameter; and
   using the multiple images of the at least one imaging region collectively to obtain a product model of the at least one product.
50. A method according to clause 49 in which the imaging parameters are selected from the group consisting of:
   a distance of an sensor from the at least one product;
   an orientation of the at least one product with respect to an imaging direction of the imaging process;
   a translational position of the at least one product transverse to an imaging direction of the imaging process; and
   a focal position of the imaging process relative to the product; and
   a frequency of electromagnetic radiation employed in the imaging process.
51. A method according to clause 49 or 50 in which the imaging process is brightfield microscopy.
52. A method according to clause 51 in which the imaging parameters include a frequency of electromagnetic radiation used in the brightfield microscopy.
53. A method according to any of clauses 49 to 52 further comprising a drive system for moving the at least one product and/or for moving the imaging unit of the imaging system, to vary the imaging parameters.
54. An imaging system comprising an imaging unit configured to perform an imaging process and a processor configured to control the imaging system to perform the method of any of clauses 49 to 53.
55. A method according to any one of clauses 1 to 46 or clauses 49 to 53 in which the product model comprises a plurality of reconstructed images having a one-to-one correspondence to the plurality of acquired images, wherein the reconstructed images represent the one or more corresponding imaging regions of the at least one product with a higher spatial resolution than the corresponding plurality of acquired images.
56. A method according to clause 55 further comprising a step of training a neural network model having a plurality of network parameters, the neural network model being configured to receive as input an image of an imaging region of a target product of the fabrication process and to generate as output a reconstructed image of the imaging region of the target product, the generated output image representing the target product with a higher spatial resolution than the input image, the training step comprising:
generating a training dataset comprising a plurality of training items, each training item comprising one of the plurality of acquired images of the first product and the corresponding reconstructed image, and
training the neural network model using the training dataset.
57. A method according to clause 56 in which the imaging process for capturing the images of the at least one product is performed by an imaging device and is characterized by at least one imaging parameter, and wherein each training item further comprises a realisation of the at least one imaging parameter that characterises the imaging process used to capture the respective image of the at least one product comprised in the training item.
58. A method according to clause 57 in which the image of the target product has been captured by performing the imaging process using the imaging device, and the neural network model is configured to receive as input the image of the primary product and a realisation of the at least one imaging parameter characterizing the imaging process used to capture the image of the primary product.
59. A method according to any one of clauses 56 to 58 in which training the neural network model using the training dataset comprises iteratively adjusting the network parameters to reduce a discrepancy between each of the reconstructed images of the training dataset and a respective output image generated by inputting the corresponding acquired image into the neural network model.
60. A method according to any one of clauses 56 to 59 in which the neural network model comprises at least one of an auto-encoder, a variational auto-encoder, and a U-Net architecture.
61. A method of training a neural network model having a plurality of network parameters and configured to generate a reconstructed image of a target object which is a product of a fabrication process from an input image of the target object, the reconstructed images representing the target object with a higher spatial resolution than the input image, the method comprising:
(i) generating a training dataset comprising a plurality of training items by:
acquiring a plurality of training images, the training images having been captured by performing an imaging process on corresponding training products of the fabrication process other than the target product, and the training images having substantially the same spatial resolution as the input image; computationally generating a respective high resolution training image for each of the plurality of training images, the respective high resolution training image having a higher spatial resolution than the corresponding training image, and
forming the plurality of training items, each training item comprising one of the plurality of training images and the corresponding high resolution training image; and
(ii) training the neural network model using the training dataset using a loss function including a term which characterizes a discrepancy between the output of the neural network model upon receiving one of the training images, and the corresponding high resolution training image.
62. A method according to clause 61 in which the target object and the training objects have been fabricated according to substantially identical design data.
63. A method according to clause 61 or clause 62 in which the imaging process for capturing the training images is performed by an imaging device and is characterized by at least one imaging parameter, and wherein each training item further comprises a realisation of the at least one imaging parameter that characterises the imaging process used to capture the respective training image comprised in the training item.
64. A method according to clause 63 in which the input image has been captured by performing the imaging process using the imaging device, and the neural network model is configured to receive as input the input image and a realisation of the at least one imaging parameter characterizing the imaging process used to capture the input image.
65. A method according to any one of clauses 61 to 64 in which the neural network model comprises at least one of an auto-encoder, a variational auto-encoder, and a U-Net architecture.
66. A method according to any one of clauses 61 to 65 in which computationally generating a respective high resolution training image for each of the plurality of training images comprises performing a method according to clause 55.
67. A method according to any one of clauses 61 to 66 in which computationally generating a respective high resolution training image for each of the plurality of training images comprises applying a deconvolution method to the training images.
68. A method according to clause 67 in which the deconvolution method is an iterative deconvolution method.
69. A method of generating a reconstructed image of a target object from an input image of the target object using a neural network trained according to any one of clauses 61 to 68, the method comprising: receiving the input image, and processing the input image using the neural network to generate the reconstructed image.

1.-15. (canceled)

16. A method of measuring at least one product of a fabrication process, the method comprising:
imaging the at least one product using an imaging system by an imaging process having at least one imaging parameter, wherein an imaging unit of the imaging system captures multiple images of at least one imaging region of the at least one product for multiple different corresponding realisations of the at least one imaging parameter; and
using the multiple images of the at least one imaging region to obtain a product model of the at least one product.

17. The method of claim 16, in which the imaging parameters are selected from the group comprising:
a distance of an sensor from the at least one product;
an orientation of the at least one product with respect to an imaging direction of the imaging process;
a translational position of the at least one product transverse to an imaging direction of the imaging process;
a focal position of the imaging process relative to the product; and
a frequency of electromagnetic radiation employed in the imaging process.

18. The method of claim 16, in which the imaging process is brightfield microscopy.

19. The method of claim 18 in which the imaging parameters include a frequency of electromagnetic radiation used in the brightfield microscopy.

20. The method of claim 16, further comprising moving, using a drive system, the at least one product and/or for moving the imaging unit of the imaging system, to vary the imaging parameters.

21. The method of claim 16, in which the product model comprises a plurality of reconstructed images having a one-to-one correspondence to the plurality of acquired images, wherein the reconstructed images represent the one or more corresponding imaging regions of the at least one product with a higher spatial resolution than the corresponding plurality of acquired images.

22. The method of claim 21, further comprising:
training a neural network model having a plurality of network parameters, the neural network model being configured to receive as input the multiple images of the at least one imaging region and to generate as output a reconstructed image of the at least one imaging region, the generated output image representing the target product with a higher spatial resolution than the input images;
wherein a training of the neural network model comprises generating a training dataset comprising a plurality of training items, each training item comprising one of the plurality of acquired images of the first product and the corresponding reconstructed image, and training the neural network model using the training dataset.

23. The method of claim 22, wherein the imaging process for capturing the images of the at least one product is performed by an imaging device and is characterized by at least one imaging parameter, and wherein each training item further comprises a realisation of the at least one imaging parameter that characterises the imaging process used to capture the respective image of the at least one product comprised in the training item.

24. The method of claim 23, wherein the image of the target product has been captured by performing the imaging process using the imaging device, and the neural network model is configured to receive as input the image of the primary product and a realisation of the at least one imaging parameter characterizing the imaging process used to capture the image of the primary product.

25. The method of claim 22, wherein training the neural network model using the training dataset comprises iteratively adjusting the network parameters to reduce a discrepancy between each of the reconstructed images of the training dataset and a respective output image generated by inputting the corresponding acquired image into the neural network model.

26. The method of claim 22, wherein the neural network model comprises at least one of an auto-encoder, a variational auto-encoder, and a U-Net architecture.

27. The method of claim 16, wherein the imaging process is performed with a scanning electron microscopy (SEM) and the images are scanning electron microscope SEM images.

28. A computing system comprising a processor and a memory, the memory storing program instructions operative, upon being performed by the processor to cause the processor to perform a method of claim 16.

29. A computer program product storing program instructions operative, upon being performed by the processor to cause the processor to perform a method of claim 16.

30. An imaging system comprising:
an imaging unit configured to perform an imaging process; and
a processor configured to control the imaging system to perform a method measuring at least one product of a fabrication process, wherein and the processor controls the imaging system to:
image at least one product using an imaging process characterized by at least one imaging parameter, wherein an imaging unit of the imaging system captures multiple images of at least one imaging region of the at least one product for multiple different corresponding realisations of the at least one imaging parameter; and
uses the multiple images of the at least one imaging region to obtain a product model of the at least one product.
